(19) United States
(12) Patent Application Publication
(10) Pub. No.: US 2023/0413616 A1
(43) Pub. Date: Dec. 21, 2023

(54) DISPLAY DEVICE AND MANUFACTURING METHOD THEREOF

(71) Applicant: LG Display Co., Ltd., Seoul (KR)

(72) Inventors: KwangIl YANG, Seoul (KR); KiYoung JUNG, Paju-si (KR)

(73) Assignee: LG Display Co., Ltd., Seoul (KR)

(21) Appl. No.: 18/142,421

(22) Filed: May 2, 2023

(30) Foreign Application Priority Data
Jun. 21, 2022 (KR) 10-2022-0075651

(51) Int. Cl. H10K 59/124; H10K 59/12; H10K 59/131

(52) U.S. Cl. CPC H10K 59/124; H10K 59/1201; H10K 59/131

(57) ABSTRACT

A display device and a manufacturing method thereof are discussed. The display device can include a buffer layer on a substrate, an active layer, a first conductor in the first region of the active layer, and a second conductor in the second region of the active layer. The surface roughness of a portion of the upper surface of the buffer layer overlapping the active layer and the surface roughness of a portion of the upper surface of the buffer layer not overlapping the active layer can be the same as, or different in a predetermined range from, each other. As a result, the reliability and characteristics of elements over the buffer layer can be improved.

### CROSS-REFERENCE TO RELATED APPLICATION

This application claims priority to Korean Patent Application No. 10-2022-0075651, filed on Jun. 21, 2022 in the Republic of Korea, the entire contents of which are hereby expressly incorporated by reference into the present application.

### BACKGROUND OF THE DISCLOSURE

### Field

The present disclosure generally relates to electronic devices including a display, and more specifically, to a display device and a method of manufacturing the display device.

### Discussion of the Related Art

Transistors are widely used as switching devices or driving devices in the field of electronic devices.

In particular, since a thin film transistor can be manufactured on a glass substrate or a plastic substrate, it is widely used as a switching device or a driving device in display devices such as a liquid crystal display device or an organic light emitting display device. In display devices including such thin film transistors, display artifacts such as image stains may occur, where identifying the cause of the image stains can be challenging.

### SUMMARY OF THE DISCLOSURE

To address such issues caused in conventional display devices, the inventors of the present disclosure have investigated the cause of display artifacts such as an image stain phenomenon, and the like, which has not been fully identified, through various experiments and analyzes over a long period of time, and developed display devices capable of preventing such display artifacts.

Through the development, the inventors have invented a manufacturing method for preventing display artifacts such as the image stain phenomenon and a display device manufactured by using the manufacturing method.

One or more embodiments of the present disclosure can provide a display device capable of preventing display artifacts such as the image stain phenomenon and a method of manufacturing the display device.

One or more embodiments of the present disclosure can provide a display device capable of preventing electrostatic phenomena and a method of manufacturing the display device.

One or more embodiments of the present disclosure can provide a display device including a buffer layer having a uniform surface roughness and a method of manufacturing the display device.

One or more embodiments of the present disclosure can provide a display device capable of enabling characteristics and reliability of elements to be uniform and a method of manufacturing the display device.

One or more embodiments of the present disclosure can provide a display device including an active layer with a short tail and a method of manufacturing the display device.

One or more embodiments of the present disclosure can provide a display device with a high aperture ratio and a method of manufacturing the display device.

According to aspects of the present disclosure, a display device can be provided that includes: a substrate; a buffer layer located on the substrate; an active layer located on the buffer layer, and including a channel region, a first region located on a first side of the channel region, and a second region located on a second side of the channel region; a first conductor located on the first region; and a second conductor located on the second region.

In one or more embodiments of the present disclosure, in the display device, a portion of an upper surface of the buffer layer overlapping the active layer and a portion of the upper surface of the buffer layer not overlapping the active layer can have a first surface roughness and a second surface roughness, respectively. The first surface roughness and the second surface roughness can be the same as, or different in a predetermined range from, each other.

In one or more embodiments of the present disclosure, the display device can further include a gate insulating layer located on the channel region, a first electrode electrically connected to the first conductor, a second electrode electrically connected to the second conductor, and a third electrode located on the gate insulating layer and overlapping the channel region.

The first conductor can be a first auxiliary electrode for an electrical connection between the first region and the first electrode, and the second conductor can be a second auxiliary electrode for an electrical connection between the second region and the second electrode.

For example, a conductive material included in the first conductor and the second conductor can include a metal included in the third electrode. In another example, a conductive material included in the first conductor and the second conductor can include a transparent conductive oxide.

In one or more embodiments of the present disclosure, the display device can further include: at least one transistor disposed in a display area or a non-display area, and including the active layer, the first conductor, the second conductor, the first electrode, the second electrode, and the third electrode; at least one line for delivering at least one signal; and a light shield located between the substrate and the buffer layer and overlapping the channel region.

In these embodiments, the at least one line can include a lower line and an upper line electrically connected to each other. The lower line can include an oxide semiconductor included in the active layer, and the upper line can include a conductive material included in the first conductor and the second conductor.

A portion of the upper surface of the buffer layer contacting the lower line can have a third surface roughness, and a portion of the upper surface of the buffer layer not overlapping the lower line and not overlapping a semiconductor material included in the active layer can have a fourth surface roughness. The third surface roughness and the fourth surface roughness can be the same as, or different in a predetermined range from, each other.

In one or more embodiments of the present disclosure, the display device can further include: a driving transistor including the active layer, the first conductor, the second conductor, the first electrode, the second electrode, and the third electrode; a storage capacitor connected between the first electrode and the third electrode of the driving transistor, and the light shield disposed between the substrate and the buffer layer and overlapping the channel region.

In these embodiments, the storage capacitor can include a first capacitor electrode, a second capacitor electrode located over the first capacitor electrode, and a third capacitor electrode located under the first capacitor electrode.

The gate insulating layer can be located between the first capacitor electrode and the second capacitor electrode, and the buffer layer can be located between the first capacitor electrode and the third capacitor electrode.

A portion of the upper surface of the buffer layer contacting the first capacitor electrode can have a fifth surface roughness, and a portion of the upper surface of the buffer layer not overlapping the first capacitor electrode and not overlapping a semiconductor material included in the active layer can have a sixth surface roughness. The fifth surface roughness and the sixth surface roughness can be the same as, or different in a predetermined range from, each other.

In one or more embodiments of the present disclosure, in the display device, the first capacitor electrode can include an oxide layer and a metal layer on the oxide layer. The oxide layer can include the oxide semiconductor included in the active layer, and the metal layer can include the conductive material included in the first conductor and the second conductor. The third capacitor electrode can include a metal included in the light shield. The second capacitor electrode can include a metal included in the third electrode.

According to aspects of the present disclosure, a method of manufacturing a display device can be provided that includes: forming a buffer layer on an entire surface of a substrate; forming an active layer on the entire upper surface of the buffer layer; forming a conductive material layer on the entire upper surface of the active layer; whiling forming one or more photoresist patterns on the conductive material layer, forming a photoresist pattern in a transistor area including a channel forming region, a first electrode forming region, and a second electrode forming region; while removing one or more portions of the conductive material layer, removing a portion of the conductive material layer not overlapping the one or more photoresist patterns; and while removing respective one or more portions of the one or more photoresist patterns, removing a portion of the photoresist pattern located in the channel forming region of the transistor area.

In one or more embodiments of the present disclosure, in the method of manufacturing the display device, the removing of the respective one or more portions of the one or more photoresist patterns can be performed in a situation where the active layer is formed on the entire upper surface of the buffer layer.

The removing of the respective one or more portions of the one or more photoresist patterns can be performed by using a plasma ashing process, this enabling electric charges generated in the active layer by the plasma ashing process to be discharged along the active layer formed on the entire upper surface of the buffer layer.

The removing of the one or more portions of the conductive material layer can be performed by using a wet etching process.

In one or more embodiments of the present disclosure, the method of manufacturing the display device can further include: after the removing of the respective one or more portions of the one or more photoresist patterns is performed, while removing one or more portions of the active layer, removing a portion of the active layer not overlapping the conductive material layer; and while further removing respective one or more portions of remaining one or more portions of the conductive material layer, removing a portion of the conductive material layer not overlapping the one or more photoresist patterns and not overlapping the channel forming region.

In one or more embodiments of the present disclosure, in the method of manufacturing the display device, after the removing of the one or more portion of the active layer is performed, a portion of an upper surface of the buffer layer overlapping the active layer can have a first surface roughness, and a portion of the upper surface thereof not overlapping the active layer can have a second surface roughness. In these embodiments, the first surface roughness and the second surface roughness can be the same as, or different in a predetermined range from, each other.

After the further removing of the respective one or more portions of remaining one or more portions of the conductive material layer is performed, the conductive material layer can remain in the first electrode forming region and the second electrode forming region.

In one or more embodiments of the present disclosure, a portion of the conductive material layer remaining in the first electrode forming region can serve as a first auxiliary electrode, and a portion of the conductive material layer remaining in the second electrode forming region can serve as a second auxiliary electrode.

In one or more embodiments of the present disclosure, the method of manufacturing the display device can further include: after the further removing of the respective one or more portions of remaining one or more portions of the conductive material layer is performed, forming a gate insulating layer; and forming a first electrode electrically connected to the first auxiliary electrode, a second electrode electrically connected to the second auxiliary electrode, and a third electrode located on the gate insulating layer and disposed in the channel forming region.

The first electrode can include a first lower electrode and a first upper electrode electrically connected to each other. The second electrode can include a second lower electrode and a second upper electrode electrically connected to each other. The third electrode can include a third lower electrode and a third upper electrode electrically connected to each other.

The first lower electrode, the second lower electrode, and the third lower electrode can commonly include a first metal, and the first upper electrode, the second upper electrode, and the third upper electrode can commonly include a second metal different from the first metal.

For example, a conductive material included in the first auxiliary electrode and the second auxiliary electrode can include a metal included in the third electrode.

A conductive material included in the first auxiliary electrode and the second auxiliary electrode can include a transparent conductive oxide.

According to one or more embodiments of the present disclosure, a display device can be provided that includes a buffer layer with a uniform surface roughness as an ashing process is performed in a situation in which an active layer is formed on the entire upper surface of the buffer layer. In the display device, characteristics and reliability of elements disposed on the buffer layer can be improved.

According to one or more embodiments of the present disclosure, a display device can be provided that is capable of enabling electric charges to be discharged along an active layer formed on the entire surface of a buffer layer, and thereby preventing static electricity, as an ashing process is performed in a situation in which the active layer is formed on the entire upper surface of the buffer layer.

According to one or more embodiments of the present disclosure, a display device can be provided that includes an active layer uniformly affected as a whole during an ashing process as the ashing process is performed in a situation in which the active layer is formed on the entire upper surface of a buffer layer. Accordingly, display artifacts such as the image stain phenomenon that can be caused by a non-uniform characteristic change of the active layer through the ashing process can be prevented or minimized.

According to one or more embodiments of the present disclosure, a display device can be provided that includes a transistor whose active layer has a short tail as the active layer is patterned through an active layer etching process after an ashing process. Accordingly, the aperture ratio of the display panel can be increased.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to aspects of the present disclosure;

FIG. 2 illustrates an example equivalent circuit of a subpixel included in the display device according to aspects of the present disclosure;

FIG. 3 illustrates another example equivalent circuit of the subpixel included in the display device according to aspects of the present disclosure;

FIG. 4 illustrates an example light shield of the subpixel included in the display device according to aspects of the present disclosure;

FIGS. 5 and 6 are cross-sectional views of example transistor structures included in the display device according to aspects of the present disclosure;

FIG. 7 is a cross-sectional view of an example structure of a storage capacitor included in the display device according to aspects of the present disclosure;

FIGS. 8 and 9 are cross-sectional views of an example display panel according to aspects of the present disclosure; and

FIGS. 10 to 20 illustrate process steps for manufacturing the display device according to aspects of the present disclosure.

### DETAILED DESCRIPTION OF THE EMBODIMENTS

Reference will now be made in detail to embodiments of the present disclosure, examples of which can be illustrated in the accompanying drawings.

In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration may be omitted or may be provided briefly. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another and may not define order or sequence. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can.”

The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

Hereinafter, with reference to the accompanying drawings, various embodiments of the present disclosure will be described in detail. All the components of each display device according to all embodiments of the present disclosure are operatively coupled and configured.

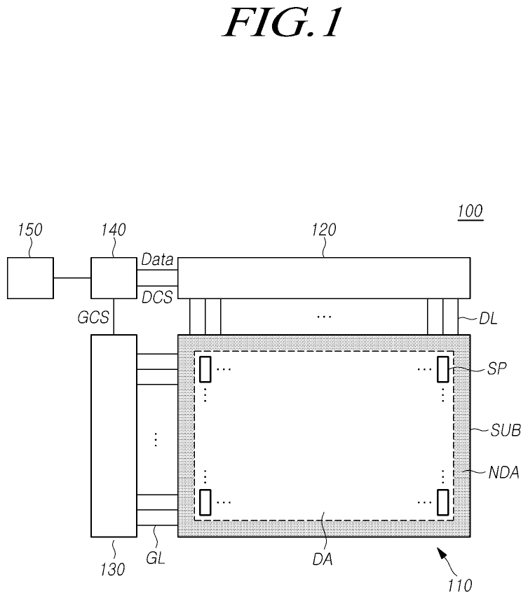

FIG. 1 illustrates an example system configuration of a display device 100 according to aspects of the present disclosure.

Referring to FIG. 1, a display device 100 according to aspects of the present disclosure can include a display panel 110 and a driving circuit for driving the display panel 110.

The driving circuit can include a data driving circuit 120, a gate driving circuit 130, and the like, and further include a controller 140 for controlling the data driving circuit 120 and the gate driving circuit 130.

The display panel 110 can include a substrate SUB, and signal lines (also referred to as traces) such as a plurality of data lines DL, a plurality of gate lines GL, and the like disposed over the substrate SUB. The display panel 110 can include a plurality of subpixels SP connected to the plurality of gate lines GL and the plurality of data lines DL.

The display panel 110 can include a display area DA in which one or more images can be displayed and a non-display area NDA located outside of the display area DA and not allowing an image to be displayed. For example, a plurality of subpixels SP for displaying images can be disposed in the display area DA of the display panel 110. The driving circuits (120, 130, and 140) can be electrically connected to, or can be mounted on, the non-display area NDA of the display panel 110, and further, one or more pads to which one or more integrated circuits or one or more printed circuits are connected, can be disposed in the non-display area NDA.

The data driving circuit 120 is a circuit for driving the plurality of data lines DL, and can supply data signals to the plurality of data lines DL. The gate driving circuit 130 is a circuit for driving the plurality of gate lines GL, and can supply gate signals to the plurality of gate lines GL. The controller 140 can supply a data control signal DCS to the data driving circuit 120 in order to control an operation time of the data driving circuit 120. The controller 140 can supply a gate control signal GCS to the gate driving circuit 130 in order to control an operation time of the gate driving circuit 130.

The controller 140 can control scanning operation to be started according to a respective time processed for each frame, convert image data inputted from other devices or other image providing sources (e.g., host systems) to a data signal form used in the data driving circuit 120 and then supply image data Data resulting from the converting to the data driving circuit 120, and control data driving to be performed at a predefined time according to a scan process.

In order to control the gate driving circuit 130, the controller 140 can supply several types of gate control signals GCS such as a gate start pulse GSP, a gate shift clock GSC, a gate output enable signal GOE, and the like.

In order to control the data driving circuit 120, the controller 140 can supply several types of data control signals DCS such as a source start pulse SSP, a source sampling clock SSC, a source output enable (SOE) signal, and the like.

The controller 140 can be implemented as a separate component from the data driving circuit 120, or integrated with the data driving circuit 120 and thus implemented in a single integrated circuit.

The data driving circuit 120 can drive a plurality of data lines DL by supplying data voltages corresponding to image data Data received from the controller 140 to the plurality of data lines DL. The data driving circuit 120 can also be referred to as a source driving circuit.

The data driving circuit 120 can include, for example, one or more source driver integrated circuits SDIC.

In one or more embodiments, each source driving circuit SDIC can be connected to the display panel 110 in a tape automated bonding (TAB) type, or connected to a conductive pad such as a bonding pad of the display panel 110 in a chip on glass (COG) type or a chip on panel (COP) type, or connected to the display panel 110 in a chip on film (COF) type.

The gate driving circuit 130 can supply a gate signal of a turn-on level voltage or a gate signal of a turn-off level voltage according to the control of the controller 140. The gate driving circuit 130 can sequentially drive a plurality of gate lines GL by sequentially supplying the gate signals of the turn-on level voltage to the plurality of gate lines GL.

In one or more embodiments, the gate driving circuit 130 can be connected to the display panel 110 in the tape automated bonding (TAB) type, or connected to a conductive pad such as a bonding pad of the display panel 110 in the chip on glass (COG) type or the chip on panel (COP) type, or connected to the display panel 110 in the chip on film (COF) type. In one or more embodiments, the gate driving circuit 130 can be disposed in the non-display area NDA of the display panel 110 in a gate in panel (GIP) type. The gate driving circuit 130 can be disposed on or over a substrate SUB, or connected to the substrate SUB. For example, in the case of the GIP type, the gate driving circuit 130 can be disposed in the non-display area NDA of the substrate SUB. The gate driving circuit 130 can be connected to the substrate SUB in the case of the chip on glass (COG) type, the chip on film (COF) type, or the like.

For example, at least one of the data driving circuit 120 and the gate driving circuit 130 can be disposed in the display area DA. In this example, at least one of the data driving circuit 120 and the gate driving circuit 130 can be disposed not to overlap subpixels SP, or disposed to be overlapped with one or more, or all, of the subpixels SP.

When a specific gate line is asserted by the gate driving circuit 130, the data driving circuit 120 can convert image data DATA received from the controller 140 into data voltages in an analog form and supply the data voltages resulting from the converting to a plurality of data lines DL.

The data driving circuit 120 can be located on, but not limited to, only one side or portion (e.g., an upper edge or a lower edge) of the display panel 110. In one or more embodiments, the data driving circuit 120 can be located in, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 130 can be located in only one side or portion (e.g., a left edge or a right edge) of the display panel 110. In one or more embodiments, the gate driving circuit 130 can be connected to two sides or portions (e.g., a left edge and a right edge) of the panel 110, or be connected to at least two of four sides or portions (e.g., an upper edge, a lower edge, the left edge, and the right edge) of the panel 110 according to driving schemes, panel design schemes, or the like.

The controller 140 can be a timing controller used in the typical display technology or a control apparatus/device capable of additionally performing other control functionalities in addition to the typical function of the timing controller. In one or more embodiments, the controller 140 can be one or more other control circuits different from the timing controller, or a circuit or component in the control apparatus/device The controller 140 can be implemented using various circuits or electronic components such as an integrated circuit (IC), a field programmable gate array (FPGA), an application specific integrated circuit (ASIC), a processor, and/or the like.

The controller 140 can be mounted on a printed circuit board, a flexible printed circuit, or the like, and can be electrically connected to the data driving circuit 120 and the gate driving circuit 130 through the printed circuit board, the flexible printed circuit, or the like.

In one or more aspects, the display device 100 can be a display including a backlight unit such as a liquid crystal display device, or can be a self-emissive display such as an organic light emitting diode (OLED) display, a quantum dot (QD) display, a micro light emitting diode (M-LED) display, and the like.

In an embodiment where the display device 100 according to aspects of the present disclosure is implemented using an OLED display, each subpixel SP can include, as a light emitting element, an organic light emitting diode (OLED), which is a self-emission element. In an embodiment where the display device 100 according to aspects of the present disclosure is implemented using a QD display, each subpixel SP can include a light emitting element configured with quantum dots, which are self-emission semiconductor crystals. In an embodiment where the display device 100 according to aspects of the present disclosure is implemented using a micro LED display, each subpixel SP can include, as a light emitting element, a micro light emitting diode (Micro LED), which is a self-emission element and including an inorganic material.

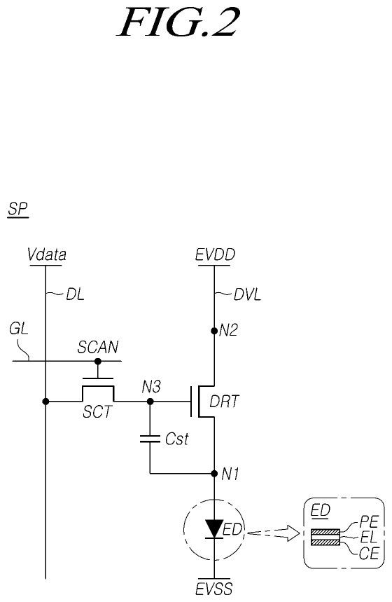

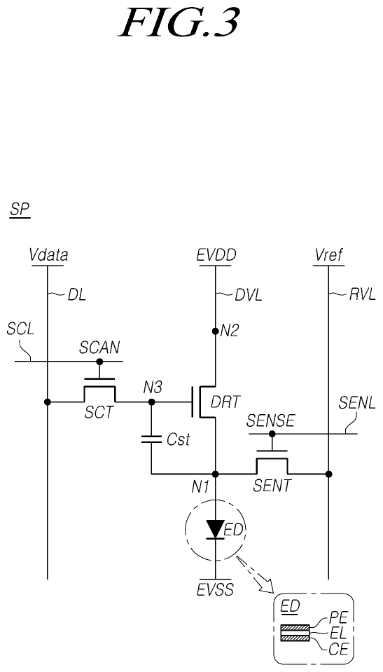

FIG. 2 illustrates an example equivalent circuit of a subpixel SP included in the display device 100 according to aspects of the present disclosure. FIG. 3 illustrates another example equivalent circuit of the subpixel SP included in the display device 100 according to aspects of the present disclosure.

Referring to FIG. 2, each of the plurality of subpixels SP disposed in the display panel 110 of the display device 100 according to aspects of the present disclosure can include a light emitting element ED, a driving transistor DRT, a scanning transistor SCT, and a storage capacitor Cst.

Referring to FIG. 2, the light emitting element ED can include a pixel electrode PE and a common electrode CE, and include an emission layer EL located between the pixel electrode PE and the common electrode CE.

The pixel electrode PE of the light emitting element ED can be an electrode disposed in each subpixel SP, and the common electrode CE can be an electrode commonly disposed in all or at least some of the plurality of subpixels SP. For example, the pixel electrode PE can be an anode electrode and the common electrode CE can be a cathode electrode. In another example, the pixel electrode PE can be a cathode electrode and the common electrode CE can be an anode electrode.

In one or more embodiments, the light emitting element ED can be an organic light emitting diode (OLED), a light emitting diode (LED), a quantum dot light emitting element or the like.

The driving transistor DRT can be a transistor for driving the light emitting element ED, and for example, include a first node N1, a second node N2, and a third node N3. In this example, the first node N1, the second node N2, and the third node N3 can also be referred to as a first electrode, a second electrode, and a third electrode, respectively.

The first node N1 of the driving transistor DRT can be a source node (source electrode) or a drain node (drain electrode) of the driving transistor DRT, and be electrically connected to the pixel electrode PE of the light emitting element ED. The second node N2 of the driving transistor DRT can be the drain node (drain electrode) or the source node (source electrode) of the driving transistor DRT, and be electrically connected to a driving voltage line DVL for transmitting a driving voltage EVDD. The third node N3 of the driving transistor DRT can be a gate node (gate electrode) of the driving transistor DRT, and be electrically connected to a source node or a drain node of the scanning transistor SCT.

The scanning transistor SCT can be controlled by a scanning gate signal SCAN, which is a type of gate signal, and be connected between the third node N3 of the driving transistor DRT and a data line DL. In other words, the scanning transistor SCT can be turned on or turned off according to a scanning gate signal SCAN supplied through a scanning gate line SCL, which is a type of gate line GL, and control an electrical connection between the data line DL and the third node N3 of the driving transistor DRT.

The scanning transistor SCT can be turned on by a scanning gate signal SCAN having a turn-on level voltage and transmit a data voltage Vdata supplied through the data line DL to the third node N3 of the driving transistor DRT.

In an example where the scanning transistor SCT is an n-type transistor, the turn-on level voltage of the scanning gate signal SCAN can be a high level voltage. In another example where the scanning transistor SCT is an p-type transistor, the turn-on level voltage of the scanning gate signal SCAN can be a low level voltage.

The storage capacitor Cst can be connected between the first node N3 and the second node N1 of the driving transistor DRT. The storage capacitor Cst can store the amount of electric charge corresponding to a voltage difference between both terminals and maintain the voltage difference between both terminals for a predetermined frame time. Accordingly, a corresponding subpixel SP can emit light for the predetermined frame time.

Referring to FIG. 3, each of the plurality of subpixels SP disposed in the display panel 110 of the display device 100 according to aspects of the present disclosure can further include a sensing transistor SENT.

The sensing transistor SENT can be controlled by a sensing gate signal SENSE, which is a type of gate signal, and be connected between the first node N1 of the driving transistor DRT and a reference voltage line RVL. In other words, the sensing transistor SENT can be turned on or turned off according to a sensing gate signal SENSE supplied through a sensing gate line SENL, which is a type of gate line GL, and control an electrical connection between the reference voltage line RVL and the first node N1 of the driving transistor DRT.

The sensing transistor SENT can be turned on by a sensing gate signal SENSE having a turn-on level voltage and transmit a reference voltage Vref supplied through the reference voltage line RVL to the first node N1 of the driving transistor DRT.

Further, the sensing transistor SENT can be turned on by the sensing gate signal SENSE having the turn-on level voltage, and transmit a voltage at the first node N1 of the driving transistor DRT to the reference voltage line RVL.

In an example where the sensing transistor SENT is an n-type transistor, the turn-on level voltage of the scanning gate signal SENSE can be a high level voltage. In another example where the sensing transistor SENT is an p-type transistor, the turn-on level voltage of the scanning gate signal SENSE can be a low level voltage.

The function of the sensing transistor SENT transmitting the voltage at the first node N1 of the driving transistor DRT to the reference voltage line RVL can be used in a sensing mode for sensing at least one characteristic value of a corresponding subpixel SP. In this case, the voltage transmitted to the reference voltage line RVL can be a voltage for calculating at least one characteristic value of the subpixel SP or a voltage to which the at least one characteristic value of the subpixel SP is added or counted.

Each of the driving transistor DRT, the scanning transistor SCT, and the sensing transistor SENT can be an n-type transistor or a p-type transistor. Herein, for convenience of description, the driving transistor DRT, the scanning transistor SCT, and the sensing transistor SENT are considered to be n-type transistors.

The storage capacitor Cst can be an external capacitor intentionally designed to be located outside of the driving transistor DRT, other than an internal capacitor, such as a parasitic capacitor (e.g., a Cgs, a Cgd), that can be formed between the gate node and the source node (or drain node) of the driving transistor DRT.

In one embodiment, the scanning gate line SCL and the sensing gate line SENL can be different gate lines GL from each other. In this embodiment, the scanning gate signal SCAN and the sensing gate signal SENSE can be separate gate signals, and respective turn-on and turn-off times of the scanning transistor SCT and the turn-on and turn-off times of the sensing transistor SENT included in one subpixel SP can be independent of each other. For example, the respective turn-on and turn-off times of the scan transistor SCT and the turn-on and turn-off times of the sensing transistor SENT included in one subpixel SP can be equal to, or different from, each other.

In another embodiment, the scanning gate line SCL and the sensing gate line SENL can be the same gate line GL. For example, the gate node of the scanning transistor SCT and the gate node of the sensing transistor SENT included in one subpixel SP can be connected to one gate line GL. In this embodiment, the scanning gate signal SCAN and the sensing gate signal SENSE can be the same gate line, and the turn-on and turn-off times of the scanning transistor SCT and the turn-on and turn-off times of the sensing transistor SENT included in one subpixel SP can be the same.

The structures of the subpixels SP shown in FIGS. 2 and 3 are merely examples, and can be variously modified by further including one or more transistors or one or more capacitors.

Further, although discussions on the subpixel structures of FIGS. 2 and 3 have been provided based on an example where the display device 100 is a self-emission display device, in an example where the display device 100 is a liquid crystal display, each subpixel SP can include a transistor, a pixel electrode, and the like.

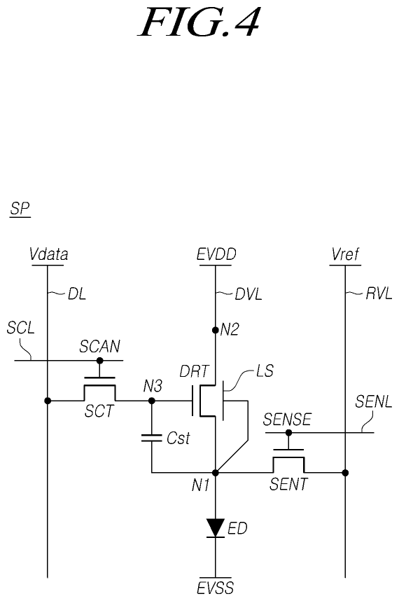

FIG. 4 illustrates an example equivalent circuit of the subpixel SP including a light shield LS in the display device 100 according to aspects of the present disclosure.

Referring to FIG. 4, a driving transistor DRT included in the subpixel SP of the display device 100 can have unique electrical characteristics such as threshold voltage, mobility, and the like. When one or more unique electrical characteristics of the driving transistor DRT vary, the current driving capability (current supplying capability) of the driving transistor DRT can vary, and thereby, the light emitting characteristics of the subpixel SP including the driving transistor DRT can also vary.

Electrical characteristics (e.g., threshold voltage, mobility, and the like) of the driving transistor DRT can vary as a driving time of the driving transistor DRT increases. In an instance, when light is irradiated to the driving transistor DRT, in particular a channel region of the driving transistor DRT, electrical characteristics (e.g., threshold voltage, mobility, etc.) of the driving transistor DRT can vary.

To address these issues, as shown in FIG. 4, in order to reduce a variance in electrical characteristics (e.g., threshold voltage, mobility, and the like) of the driving transistor DRT, a light shield LS can be disposed around the driving transistor DRT. For example, the light shield LS can be disposed under a channel region of the driving transistor DRT.

The light shield LS can serve as a body of the driving transistor DRT while being located under the channel region of the driving transistor DRT, in addition to serving to shield light.

A body effect can occur in the driving transistor DRT. In order to reduce influence of the body effect, the light shield LS serving as the body of the driving transistor DRT can be electrically connected to a first node N1 of the driving transistor DRT. The first node N1 of the driving transistor DRT can be, for example, the source node of the driving transistor DRT.

In one or more embodiments, the light shield LS can be disposed under a respective channel region of one or more other transistors (e.g., SCT and/or SENT), as well as under the channel region of the driving transistor DRT,

In one or more embodiments, transistors (DRT, SCT, and SENT) can be disposed in each subpixel SP included in the display area DA of the display panel 110. In one or more embodiments where the gate driving circuit 130 is implemented in the gate in panel (GIP) type in the non-display area NDA of the display panel 110, a plurality of transistors included in the gate driving circuit 130 implemented in the GIP type can be disposed in the non-display area NDA of the display panel 110.

Meanwhile, conventional display devices can have issues associated with display artifacts such as an image stain phenomenon, and the like. Such an image stain phenomenon can lead image quality to become poor; however, it may not be easy to find the cause of the image staining phenomenon. To address this issue, a manufacturing method capable of preventing display artifacts has been developed through various experiments and analyzes over a long period of time.

As a result, according to one or more embodiments of the present disclosure, provided herein are a manufacturing method for preventing display artifacts such as the image stain phenomenon, and a display device manufactured by using the manufacturing method. Hereinafter, in one or more aspects, the display device 100 capable of preventing or minimizing display artifacts such as the image stain phenomenon and a method of manufacturing the display device 100 will be discussed with reference to the drawings.

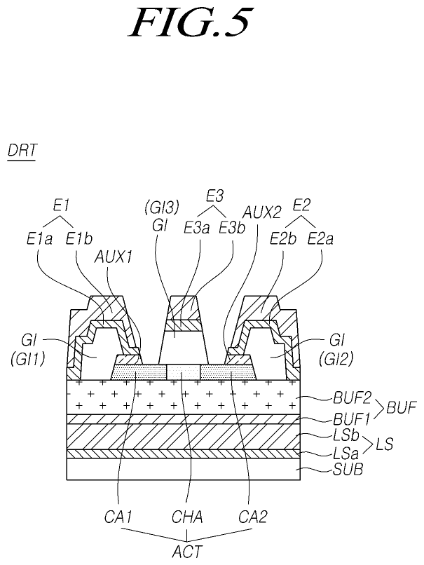

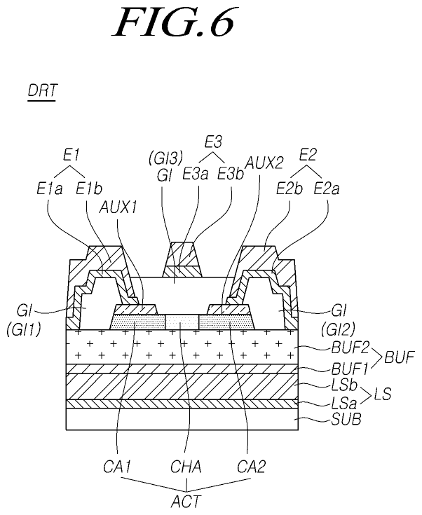

FIGS. 5 and 6 are cross-sectional views of example transistor structures included in the display device 100 according to aspects of the present disclosure.

In one or more embodiments, the display panel 110 can include a display area DA where one or more images can be displayed and a non-display area NDA different from the display area DA. A plurality of transistors and a plurality of capacitors can be disposed in the display area DA and/or the non-display area NDA.

In one or more embodiments, at least some of the transistors disposed in the display panel 110 can be transistors (DRT, SCT, and/or SENT) included in each of a plurality subpixels SP disposed in the display area DA of the display panel 110.

In one or more embodiments, at least some of the transistors disposed in the display panel 110 can be transistors included in the gate driving circuit 130 implemented in the GIP type in the non-display area NDA of the display panel 110.

In one or more embodiments, at least some of the capacitors disposed in the display panel 110 can be storage capacitors Cst included in each of the plurality subpixels SP of the display area DA of the display panel 110, and/or can storage capacitors Cst included in the gate driving circuit 130 implemented in the GIP type in the non-display area NDA of the display panel 110.

Hereinafter, discussions on a transistor structure according to embodiments of the present disclosure are provided based on, as an example transistor, a driving transistor DRT included in each subpixel SP disposed in the display area DA, and discussions on a capacitor structure according to embodiments of the present disclosure are provided based on, as an example capacitor, a storage capacitor Cst included in each subpixel SP disposed in the display area DA.

Referring to FIGS. 5 and 6, in one or more embodiments, the display panel 110 of the display device 100 can include a substrate SUB, a buffer layer BUF on the substrate SUB, an active layer BUF on the buffer layer BUF, a gate insulating layer GI on the active layer ACT, and a third electrode E3 on the gate insulating layer GI, and further include a light shield LS disposed under the active layer ACT.

In one or more embodiments, the driving transistor DRT disposed in the display panel 110 can include a first electrode E1, a second electrode E2, the third electrode E3, and the active layer ACT. In these embodiments, the first and second electrodes (E1 and E2) can be source and drain electrodes of the driving transistor DRT, respectively. In another embodiment, the first and second electrodes (E1 and E2) can be drain and source electrodes of the driving transistor DRT, respectively.

The active layer ACT can include a channel area CHA overlapping the third electrode E3, a first region CA1 located on a first side of the channel region CHA, and a second region CA2 located on a second side of the channel area CHA.

The channel region CHA can overlap the third electrode E3. A gate insulating layer GI can be disposed between the channel region CHA and the third electrode E3.

The first region CA1 and the second region CA2 can be conductivity-enabled regions.

Herein, when the first region CA1 and the second region CA2 are conductivity-enabled regions, the first region CA1 is referred to as a first conductivity-enabled region CA1, and the second region CA2 is referred to as a second conductivity-enabled region CA2.

The active layer ACT can include an oxide semiconductor material. The oxide semiconductor material can be a semiconductor material obtained by controlling conductivity and adjusting a bandgap through doping of an oxide material, and can generally be a transparent semiconductor material having a wide bandgap. For example, such an oxide semiconductor material can include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like. The active layer ACT can be formed in a single layer or a multilayer. In an example where the active layer ACT is formed in a multilayer, the active layer ACT can include a multilayer formed with a same semiconductor material or a multilayer formed with two or more different semiconductor materials. In an example where the active layer ACT includes an oxide semiconductor material, a driving transistor DRT including this type of active layer ACT is referred to as an oxide thin film transistor.

The third electrode E3 can be located on the gate insulating layer GI and can overlap the channel region CHA of the active layer ACT.

The first electrode E1 can be electrically connected to the first conductivity-enabled region CA1 of the active layer ACT. The second electrode E2 can be electrically connected to the second conductivity-enabled region CA2 of the active layer ACT.

Each, or one or more, of the first electrode E1, the second electrode E2, and the third electrode E3 can be formed in a single layer or a multilayer. For example, each of the first electrode E1, the second electrode E2, and the third electrode E3 can include copper (CU), aluminum (AL), molybdenum (Mo), titanium (Ti), molybdenum-titanium (MoTi) or the like.

In an example where at least one of the first electrode E1, the second electrode E2, and the third electrode E3 is formed in a multilayer, the at least one electrode (E1, E2, and/or E3) formed in a multilayer can include a lower electrode and an upper electrode electrically connected to each other.

The lower electrode can include a first metal, and the upper electrode can include a second metal different from the first metal. For example, the first metal can include molybdenum (Mo), titanium (Ti), molybdenum-titanium (MoTi), or the like. The second metal can include copper (Cu) aluminum (Al), or the like. Hereinafter, discussions that follow are provided based on examples where the first metal is molybdenum-titanium (MoTi), and the second metal is copper (Cu).

Referring to FIGS. 5 and 6, the first electrode E1 can include a first lower electrode Ela and a first upper electrode E1b electrically connected to each other. The first lower electrode Ela can include the first metal (e.g., MoTi), and the first upper electrode E1b can include the second metal (e.g., Cu) different from the first metal.

Referring to FIGS. 5 and 6, the second electrode E2 can include a second lower electrode E2a and a second upper electrode E2b electrically connected to each other. The second lower electrode E2a can include the first metal (e.g., MoTi), and the second upper electrode E2b can include the second metal (e.g., Cu).

Referring to FIGS. 5 and 6, the third electrode E3 can include a third lower electrode E3a and a third upper electrode E3b electrically connected to each other. The third lower electrode E3a can include the first metal (e.g., MoTi), and the third upper electrode E3b can include the second metal (e.g., Cu).

As described above, the first lower electrode E1a, the second lower electrode E2a, and the third lower electrode E3a can commonly include the first metal. The first upper electrode E1b, the second upper electrode E2b, and the third upper electrode E3b can commonly include the second metal different from the first metal.

Referring to FIGS. 5 and 6, in one or more embodiments, the driving transistor DRT disposed in the display panel 110 can further include a first conductor AUX1 on the first conductive region CA1 and a second conductor AUX2 on the second conductive region CA2.

The first conductor AUX1 can be located between the first conductivity-enabled region CA1 and the first electrode E1, and can electrically connect the first conductivity-enabled region CA1 and the first electrode E1. The second conductor AUX2 can be located between the second conductivity-enabled region CA2 and the second electrode E2, and can electrically connect the second conductivity-enabled region CA2 and the second electrode E2.

A conductive material included in each of the first conductor AUX1 and the second conductor AUX2 can include, for example, a metal included in the first electrode E1, the second electrode E2, or the third electrode E3. In this example, the metal included in the first electrode E1, the second electrode E2, and the third electrode E3 can be copper (CU), aluminum (AL), molybdenum (Mo), titanium (Ti), molybdenum-titanium (MoTi) or the like.

In an example where the first electrode E1, the second electrode E2, or the third electrode E3 has a double metal structure, the conductive material included in each of the first conductor AUX1 and the second conductor AUX2 can include the first metal (e.g., MoTi) included in the first lower electrode E1a, the second lower electrode E2a, or the third lower electrode E3a.

In another example, a conductive material included in each of the first conductor AUX1 and the second conductor AUX2 can include a conductive oxide. For example, the conductive oxide can include at least one of a transparent conductive oxide (TCO), a nitroxide, an organic material, and the like. For example, the transparent conductive oxide (TCO) can include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), fluorine-doped transparent oxide (FTO), and the like. The nitric oxide can include zinc oxynitride (ZnON), and the like.

Referring to FIGS. 5 and 6, the gate insulating layer GI can include a first gate insulating layer part GI1, a second gate insulating layer part GI2, and a third gate insulating layer part GI3.

Referring to FIGS. 5 and 6, the first gate insulating layer part GI1 can be disposed such that the first gate insulating layer part GI1 covers, among first and second ends of the first conductor AUX1, the first end farther away from the channel region CHA of the active layer ACT. The second gate insulating layer part GI2 can be disposed such that the second gate insulating layer part GI2 covers, among first and second ends of the second conductor AUX2, the second end farther away from the channel region CHA of the active layer ACT.

Referring to FIGS. 5 and 6, the first gate insulating layer part GI1 and the second gate insulating layer part GI2 may not overlap the channel region CHA of the active layer ACT. The third gate insulating layer part GI3 can be located on the channel region CHA of the active layer ACT.

Referring to FIGS. 5 and 6, the first electrode E1 can be located on one or more upper surfaces and one or more side surfaces of the first gate insulating layer part GI1. For example, the first electrode E1 can contact a portion of the upper surface of the first conductor AUX1 while being located on a side surface of the first gate insulating layer part GI1. The second electrode E2 can be located on one or more upper surfaces and one or more side surfaces of the second gate insulating layer part GI2. For example, the second electrode E2 can contact a portion of the upper surface of the second conductor AUX2 while being located on a side surface of the second gate insulating layer part GI2. The third electrode E3 can be located on the upper surface of the third gate insulating layer portion GI3.

As described above, the first conductor AUX1 can be an auxiliary electrode for providing an electrical connection between the first conductivity-enabled region CA1 and the first electrode E1, and the second conductor AUX2 can be an auxiliary electrode for providing an electrical connection between the second conductivity-enabled region CA2 and the second electrode E2. Considering such functions of the first and second conductors AUX1 and AUX2, hereinafter, the first and second conductors AUX1 and AUX2 can be referred to as first and second auxiliary electrodes AUX1 and AUX2, respectively.

Referring to FIGS. 5 and 6, the buffer layer BUF can be formed in a single layer or a multilayer. For example, the buffer layer BUF can include at least one of various insulating materials such as silicon nitride (SiNx), silicon dioxide (SiO2), and/or the like.

Referring to FIGS. 5 and 6, when the buffer layer BUF is formed in a multilayer, the buffer layer BUF can include a first buffer layer BUF1 and a second buffer layer BUF2. For example, the first buffer layer BUF1 can include silicon nitride (SiNx), and the second buffer layer BUF2 can include silicon dioxide (SiO2). In another example, the first buffer layer BUF1 can include silicon dioxide (SiO2), and the second buffer layer (BUF2) can include silicon nitride (SiNx).

The gate insulating layer GI located on the channel region CHA of the active layer ACT can have an etched structure as shown in FIG. 5 or an unetched structure as shown in FIG. 6.

Referring to FIG. 5, in one or more embodiments, the driving transistor DRT disposed in the display panel 110 can have a structure in which the gate insulating layer GI is etched (which can also referred to as a gate insulating layer etch structure). In these embodiments, the gate insulating layer GI may not be disposed between the first electrode E1 and the third electrode E3.

Referring to FIG. 5, the first auxiliary electrode AUX1 can be located on all or a portion of the first conductivity-enabled region CA1 of the active layer ACT. All or a portion of the first auxiliary electrode AUX1 can be exposed through an opening (etch hole) of the gate insulating layer GI. The first electrode E1 can be connected to the portion of the first auxiliary electrode AUX1, which is exposed through the opening (etch hole) of the gate insulating layer GI. Accordingly, the first electrode E1 can be electrically connected to the first conductivity-enabled region CA1 of the active layer ACT through the first auxiliary electrode AUX1.

The second auxiliary electrode AUX2 can be located on all or a portion of the second conductivity-enabled region CA2 of the active layer ACT. All or a portion of the second auxiliary electrode AUX2 can be exposed through another opening (etch hole) of the gate insulating layer GI. The second electrode E2 can be connected to the portion of the second auxiliary electrode AUX2, which is exposed through the another opening (etch hole) of the gate insulating layer GI. Accordingly, the second electrode E2 can be electrically connected to the second conductivity-enabled region CA2 of the active layer ACT through the second auxiliary electrode AUX2.

Referring to FIG. 6, in one or more embodiments, the driving transistor DRT disposed on the display panel 110 can have a structure in which the gate insulating layer GI is not etched (which can also referred to as a gate insulating layer etch-less structure). In these embodiments, the gate insulating layer GI can be disposed between the first electrode E1 and the third electrode E3 and between the second electrode E2 and the third electrode E3.

Referring to FIG. 6, the first auxiliary electrode AUX1 can be located on all or a portion of the first conductivity-enabled region CA1 of the active layer ACT. The first electrode E1 can be connected to at least a portion of the first auxiliary electrode AUX1 through a contact hole formed in the gate insulating layer GI. Accordingly, the first electrode E1 can be electrically connected to the first conductivity-enabled region CA1 of the active layer ACT through the first auxiliary electrode AUX1.

The second auxiliary electrode AUX2 can be located on all or a portion of the second conductivity-enabled region CA2 of the active layer ACT. The second electrode E2 can be connected to at least a portion of the second auxiliary electrode AUX2 through another contact hole formed in the gate insulating layer GI. Accordingly, the second electrode E2 can be electrically connected to the second conductivity-enabled region CA2 of the active layer ACT through the second auxiliary electrode AUX2.

Referring to FIG. 5, in one or more embodiments, the light shield LS included in the display panel 110 of the display device 100 can be located between the substrate SUB and the buffer layer BUF, and overlap the channel region CHA of the active layer ACT.

The light shield LS can be formed in a single layer or a multilayer. For example, each of the first electrode E1, the second electrode E2, and the third electrode E3 can include copper (CU), aluminum (AL), molybdenum (Mo), titanium (Ti), molybdenum-titanium (MoTi) or the like.

Referring to FIGS. 5 and 6, in the example where the light shield LS is formed in a multilayer, the light shield LS can include a lower light shield LSa and an upper light shield LSb on the lower light shield LSa.

Referring to FIGS. 5 and 6, the lower light shield LSa can include the first metal (e.g., MoTi) included in the first lower electrode E1a, the second lower electrode E2a, and/or the third lower electrode E3a. The upper light shield LSb can include the second metal (e.g., Cu) included in the first upper electrode E1b, the second upper electrode E2b, and/or the third upper electrode E3b. For example, the first metal can include molybdenum (Mo), titanium (Ti), molybdenum-titanium (MoTi), or the like. The second metal can include copper (Cu) aluminum (Al), or the like.

Referring to FIGS. 5 and 6, the lower light shield LSa and the upper light shield LSb included in the light shield LS may, or can not, be electrically connected to each other.

Referring to FIGS. 5 and 6, the first lower electrode Ela or the second lower electrode E2a can be connected to the upper light shield LSb through through-holes of the buffer layer BUF and the gate insulating layer GI. Accordingly, the light shield LS can be electrically connected to the first node N1 of the driving transistor DRT shown in FIG. 4.

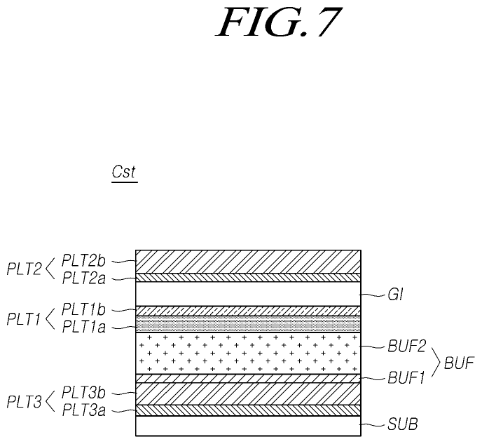

FIG. 7 is a cross-sectional view of an example structure of a storage capacitor Cst included in the display device 100 according to aspects of the present disclosure.

Referring to FIG. 7, the storage capacitor Cst can include a first capacitor electrode PLT1 and a second capacitor electrode PLT2 overlapping the first capacitor electrode PLT1. A gate insulating layer GI (e.g., the gate insulating layer GI of FIGS. 5 and 6) can be located between the first capacitor electrode PLT1 and the second capacitor electrode PLT2.

Referring to FIG. 7, in one or more embodiments, the storage capacitor Cst can further include a third capacitor electrode PLT3. In these embodiments, the storage capacitor Cst can include the first capacitor electrode PLT1, the second capacitor electrode PLT2 located over the first capacitor electrode PLT1, and a third capacitor electrode PLT3 located under the first capacitor electrode PLT1.

Referring to FIG. 7, the gate insulating layer GI can be located between the first capacitor electrode PLT1 and the second capacitor electrode PLT2. The buffer Layer BUF can be located between the first capacitor electrode PLT1 and the third capacitor electrode PLT3.

Referring to FIG. 7, the third capacitor electrode PLT3 of the storage capacitor Cst can be any one of an electrode formed by the extending of the light shield LS, an electrode electrically connected to the light shield LS, or an electrode including the same metal as a metal included in the light shield LS.

In an example where the light shield LS includes the lower light shield LSa and the upper light shield LSb, the third capacitor electrode PLT3 can include a third lower capacitor electrode PLT3a and a third upper capacitor electrode PLT3b.

The third lower capacitor electrode PLT3a can be any one of an electrode formed by the extending of the lower light shield LSa, an electrode electrically connected to the lower light shield LSa, or an electrode including the same metal as a metal included in the lower light shield LSa.

The third upper capacitor electrode PLT3b can be any one of an electrode formed by the extending of the upper light shield LSb, an electrode electrically connected to the upper light shield LSb, or an electrode including the same metal as a metal included in the upper light shield LSb.

Referring to FIG. 7, in one or more embodiments, the first capacitor electrode PLT1 of the storage capacitor Cst can be formed in a single layer including the same semiconductor material as a semiconductor material included in the active layer ACT In these embodiments, the first capacitor electrode PLT1 can be an electrode conductively enabled with the same semiconductor material as the semiconductor material of the active layer ACT.

In an example where the first auxiliary electrode AUX1 and the second auxiliary electrode AUX2 are further disposed on the active layer ACT, the first capacitor electrode PLT1 can include a first lower capacitor electrode PLT1a and a first upper capacitor electrode PLT1b.

The first lower capacitor electrode PLT1a can include, for example, the semiconductor material of the active layer ACT. In this example, the first lower capacitor electrode PLT1a can be a conductivity-enabled semiconductor material or a non-conductivity-enabled semiconductor material.

The first upper capacitor electrode PLT1b can include the same material as the first auxiliary electrode AUX1 and the second auxiliary electrode AUX2. For example, the first upper capacitor electrode PLT1b can include a metal (e.g., MoTi) included in the first electrode E1, the second electrode E2, or the third electrode E3. In another example, the first upper capacitor electrode PLT1b can include a conductive oxide (e.g., indium zinc oxide (IZO), and the like).

Referring to FIG. 7, the second capacitor electrode PLT2 of the storage capacitor Cst can be any one of an electrode formed by the extending of the first electrode E1, the second electrode E2, or the third electrode E3, an electrode electrically connected to the first electrode E1, the second electrode E2, or the third electrode E3, or an electrode including the same metal as the first electrode E1, the second electrode E2, or the third electrode E3.

In an example where the third electrode E3 includes the third lower electrode E3a and the third upper electrode E3b, the second capacitor electrode PLT2 can include a second lower capacitor electrode PLT2a and a second upper capacitor electrode PLT2b.

The second lower capacitor electrode PLT2a can include a metal included in the respective lower electrode (E1a, E2a, or E3a) of the first electrode E1, the second electrode E2, or the third electrode E3.

The second upper capacitor electrode PLT2b can include a metal included in the respective upper electrode (E1b, E2b, or E3b) of the first electrode E1, the second electrode E2, or the third electrode E3.

The storage capacitor Cst can be electrically connected between the source and gate nodes of the driving transistor DRT. For example, the source node of the driving transistor DRT can be the first electrode E1 or the second electrode E2, and the gate node of the driving transistor DRT can be the third electrode E3. The first electrode E1 or the second electrode E2, which is the source node of the driving transistor DRT, can be electrically connected to the light shield LS.

For example, the second capacitor electrode PLT2 can be electrically connected to the first electrode E1 or the second electrode E2, which is the source node of the driving transistor DRT. The first capacitor electrode PLT1 can be electrically connected to the third electrode E3, which is the gate node of the driving transistor DRT. The third capacitor electrode PLT3 can be electrically connected to the first electrode E1 or the second electrode E2, which is the source node of the driving transistor DRT. Accordingly, as the storage capacitor Cst has a structure in which two capacitors are connected in parallel, the capacitance of the storage capacitor Cst can increase.

The two capacitors connected in parallel to form the storage capacitor Cst can include a first capacitor formed between the first capacitor electrode PLT1 and the second capacitor electrode PLT2, and a second capacitor formed between the first capacitor electrode PLT1 and the third capacitor electrodes PLT3.

The structure of the storage capacitor Cst discussed above will be described again as follows.

The storage capacitor Cst can include the first capacitor electrode PLT1, the second capacitor electrode PLT2 located over the first capacitor electrode PLT1, and the third capacitor electrode PLT3 located under the first capacitor electrode PLT1.

The first capacitor electrode PLT1 can include an oxide layer and a metal layer on the oxide layer.

The oxide layer included in the first capacitor electrode PLT1 can represent the first lower capacitor electrode PLT1a, and include an oxide semiconductor included in the active layer ACT. The metal layer included in the first capacitor electrode PLT1 can represent the first upper capacitor electrode PLT1b, and include a conductive material included in the first conductor AUX1 and the second conductor AUX2.

The third capacitor electrode PLT3 can include a metal included in the light shield. The second capacitor electrode PLT2 can include a metal included in the third electrode E3 of the driving transistor DRT.

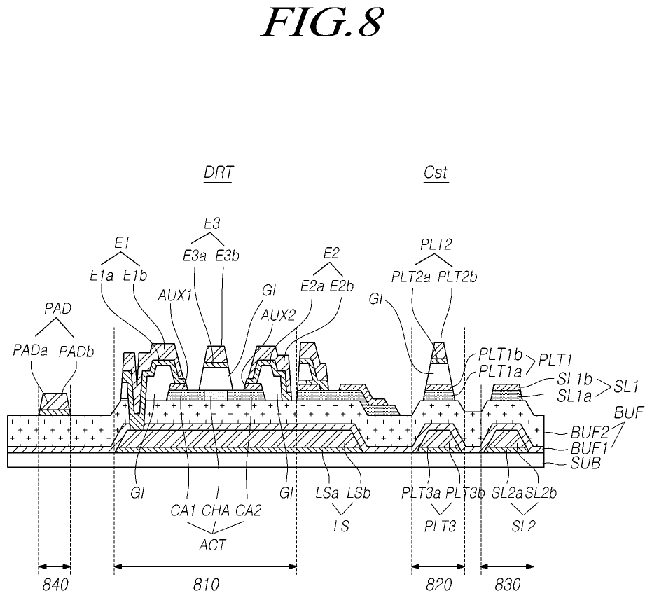

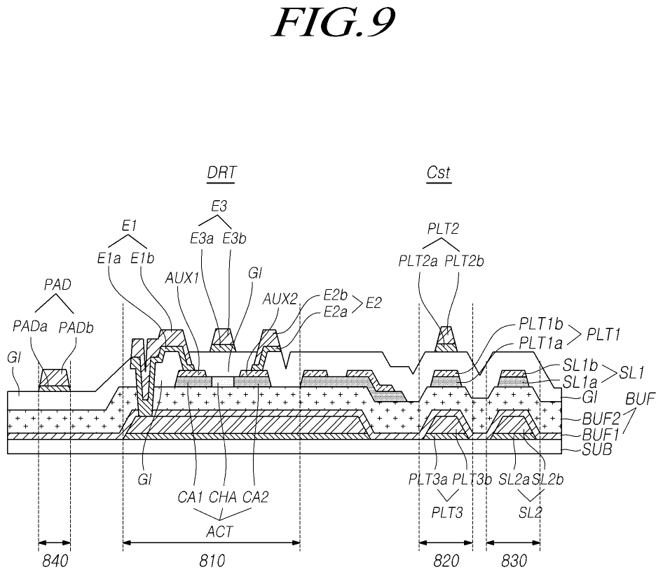

FIGS. 8 and 9 are example cross-sectional views of the display panel 110 according to aspects of the present disclosure.

Particularly, FIG. 8 illustrates an example portion of the display panel 110 in which the driving transistor DRT of FIG. 5 and the storage capacitor Cst of FIG. 7 are disposed. FIG. 9 illustrates an example portion of the display panel 110 in which the driving transistor DRT of FIG. 6 and the storage capacitor Cst of FIG. 7 are disposed.

Referring to FIGS. 8 and 9, in one or more embodiments, the display panel 110 can include a transistor area 810, a capacitor area 820, a line area 830, and a pad area 840.

The transistor area 810 can be present in both the display area DA and the non-display area NDA of the display panel 110. The transistor areas 810 of FIGS. 8 and 9 are example transistor areas included in the display area DA.

The driving transistor DRT disposed in the transistor area 810 of FIG. 8 can have the transistor structure of FIG. 5. The driving transistor DRT disposed in the transistor area 810 of FIG. 9 can have the transistor structure of FIG. 6.

Referring to FIGS. 8 and 9, the first electrode E1 of the driving transistor DRT can be electrically connected to the light shield LS through a through-hole of the buffer layer BUF.

The storage capacitor Cst of FIG. 7 can be disposed in the capacitor areas 820 of each of FIGS. 8 and 9.

Referring to FIGS. 8 and 9, one or more lines (SL1 and/or SL2) for delivering one or more signals can be disposed in the line area 830. For example, the one or more lines (SL1 and/or SL2) can represent a data line DL, a driving voltage line DVL, a reference voltage line RVL, and/or the like.

Referring to FIGS. 8 and 9, the one or more lines (SL1 and/or SL2) can include a first line SL1 disposed on the buffer layer BUF and a second line SL2 disposed underneath the buffer layer BUF.

Referring to FIGS. 8 and 9, the first line SL1 can include a first lower line SL1a and a first upper line SL1b electrically connected to each other.

Referring to FIGS. 8 and 9, the first lower line SL1a can include an oxide semiconductor included in the active layer ACT. For example, the oxide semiconductor included in the first lower line SL1a can be in a conductivity-enabled state where the oxide semiconductor became conductive or can be in a non-conductivity-enabled state.

Referring to FIGS. 8 and 9, the first upper line SL1b can include a conductive material included in the first conductor AUX1, which is the first auxiliary electrode, and the second conductor AUX2, which is the second auxiliary electrode. For example, the conductive material included in the first and second conductors AUX1 and AUX2 can include a metal included in the third electrode E3. In another example, the conductive material included in the first and second auxiliary electrodes AUX1 and AUX2 can include a transparent conductive oxide.

Referring to FIGS. 8 and 9, the second line SL2 can include a second lower line SL2a and a second upper line SL2b electrically connected to each other. The second lower line SL2a can include a metal included in the lower light shield LSa. The second upper line SL2b can include a metal included in the upper light shield LSb.

Referring to FIGS. 8 and 9, the pad area 840 can be located in the non-display area NDA located outside of the display area DA, and a pad part PAD including one or more pads can be disposed in the pad area 840 of the non-display area NDA. An integrated circuit can be electrically connected to the pad part PAD. For example, the integrated circuit electrically connected to the pad part PAD can be a source driver integrated circuit in which the data driving circuit 120 is implemented.

The pad part PAD can include a lower pad PADa and an upper pad PADb connected to each other. The lower pad PADa can include a metal included in the first to third lower electrodes (E1a, E2a, and E3a) of the first to third electrodes (E1, E2, and E3), or include a metal included in the first and second auxiliary electrodes AUX1 and AUX2. The upper pad PADb can include a metal included in the first to third upper electrodes (E1b, E2b, and E3b) of the first to third electrodes (E1, E2, and E3).

Referring to FIG. 9, in an example where the driving transistor DRT has a gate insulating layer etch-less structure, the gate insulating layer GI can be disposed in the entire area of the display panel 110. Accordingly, first and second parts P1 and P2 of the gate insulating layer GI can extend under the pad part PAD disposed in the pad area, and further extend over a line SL disposed in the line area 830.

Referring to FIGS. 8 and 9, in one or more embodiments, the buffer layer BUF included in the display panel 110 can have a smooth upper surface regardless of locations. In other words, the surface roughness of the upper surfaces of the buffer layer BUF can be uniform regardless of locations. The surface roughness can refer to the size or degree of one or more irregularities on the surface that can occur in the manufacturing process, and can represent a distance between the highest point of the surface (or the highest point of one or more irregularities) and lowest point of the surface (or the lowest point of one or more irregularities).

In one or more embodiments, referring to FIGS. 8 and 9, in the display panel 110, a portion of an upper surface of the buffer layer BUF overlapping the active layer ACT can have a first surface roughness, and another portion of the upper surface of the buffer layer BUF not overlapping the active layer ACT can have a second surface roughness.

For example, the first surface roughness and the second surface roughness can be the same as each other. In another example, the first surface roughness and the second surface roughness can have a difference in a predefined range (e.g., ±1%, ±2%, ±3%, ±4%, ±5%, ±10%, or the like). For example, the first surface roughness can be greater or less than the second surface roughness. The first surface roughness and the second surface roughness can have a difference in a range of 1%, 2%, 3%, 4%, 5%, or 10% (i.e., a difference in sizes of respective irregularities present on the portions of the surface). In particular, at a boundary with an edge of the active layer ACT, the first surface roughness can have a difference (i.e., a difference in sizes of irregularities) in a range of 10% from the second surface roughness.

In an instance, stepped portions can be present in a portion of the upper surface of the buffer layer BUF forming a boundary with an edge of the active layer ACT. For example, at the boundary with an edge of the active layer ACT, a difference in height (i.e., a step difference) between a portion of the upper surface of the buffer layer BUF overlapping the active layer ACT and a portion of the upper surface of the buffer layer BUF not overlapping the active layer ACT.

For example, referring to FIGS. 8 and 9, in the display panel 110, a portion of the upper surface of the buffer layer BUF contacting the first lower line SL1a can have a third surface roughness, and a portion of the upper surface of the buffer layer BUF not overlapping the first lower line SL1a and not overlapping a semiconductor material included in the active layer ACT can have a fourth surface roughness.

For example, the third surface roughness and the fourth surface roughness can be the same as each other. In another example, the third surface roughness and the fourth surface roughness can have a difference in a predefined range (e.g., ±1%, ±2%, ±3%, ±4%, ±5%, ±10%, or the like). The third surface roughness can be the same as the first surface roughness, and the fourth surface roughness can be the same as the second surface roughness. For example, the third surface roughness can be greater or less than the fourth surface roughness. The third surface roughness and the fourth surface roughness can have a difference in a range of 1%, 2%, 3%, 4%, 5%, or 10% (i.e., a difference in sizes of respective irregularities present on the portions of the surface). In particular, at a boundary with an edge of a layer in which a semiconductor material included in the active layer ACT is formed, the third surface roughness can have a difference (i.e., a difference in sizes of irregularities) in a range of 10% from the fourth surface roughness.

For example, referring to FIGS. 8 and 9, in the display panel 110, a portion of the upper surface of the buffer layer BUF contacting the first capacitor PLT1 can have a fifth surface roughness, and a portion of the upper surface of the buffer layer BUF not overlapping the first capacitor PLT1 and not overlapping a semiconductor material included in the active layer ACT can have a sixth surface roughness.

For example, the fifth surface roughness and the sixth surface roughness can be the same as each other. In another example, the fifth surface roughness and the sixth surface roughness can have a difference in a predefined range (e.g., ±1%, ±2%, ±3%, ±4%, ±5%, ±10%, or the like). The fifth surface roughness can be the same as the first surface roughness, and the sixth surface roughness can be the same as the second surface roughness. For example, the fifth surface roughness can be greater or less than the sixth surface roughness. The fifth surface roughness and the sixth surface roughness can have a difference in a range of 1%, 2%, 3%, 4%, 5%, or 10% (i.e., a difference in sizes of respective irregularities present on the portions of the surface). In particular, at a boundary with an edge of a layer in which a semiconductor material included in the active layer ACT is formed, the fifth surface roughness can have a difference (i.e., a difference in sizes of irregularities) in a range of 10% from the sixth surface roughness.

As described above, the buffer layer BUF can have the smooth upper surface regardless of locations thereof. Depending on the characteristics of the buffer layer BUF, characteristics and reliability of elements such as driving transistors DRT and storage capacitors Cst can be improved.

Hereinafter, a method of manufacturing the display device 100 according to aspects of the present disclosure will be described. In the display device 100 manufactured by a method according to one or more embodiments of the present disclosure, the upper surface of the buffer layer BUF can be smooth regardless of locations thereof.

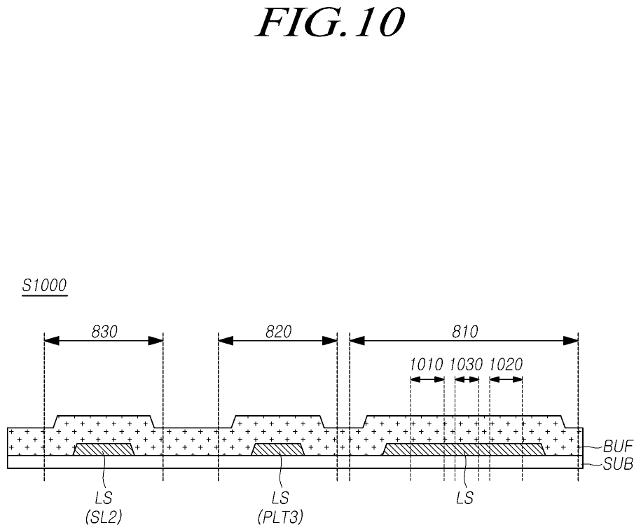

FIGS. 10 to 20 illustrate respective cross-sectional views in process steps (S1000, S1100, S1200, S1300, S1400, S1500, S1600, S1700, S1800, S1900, and S2000) for manufacturing the display device 100 according to aspects of the present disclosure.

Referring to FIGS. 10 to 20, in one or more embodiments, the method of manufacturing the display panel 110 of the display device 100 can include a buffer layer deposition process S1000, an active layer deposition process S1100, a conductive material layer deposition process S1200, a photoresist pattern forming process S1300, a first conductive material layer etching process S1400, an ashing process S1500, an active layer etching process S1600, a secondary conductive material layer etching process S1700, a photoresist pattern removing process S1800, a gate insulating layer forming process S1900, a transistor electrode forming process S2000, and the like.

Hereinafter, for convenience of explanation, discussions are provided based on examples where a light shield (e.g., the light shield LS in figures discussed above) and first to third electrodes (e.g., the first to third electrodes E1 to E3 in figures discussed above) have a single layer electrode structure (or a single metal electrode structure). Likewise, discussions are also provided based on examples where a second capacitor electrode (e.g., the second capacitor electrode PLT2 in figures discussed above) and a third capacitor electrode (e.g., the third capacitor electrode PLT3 in figures discussed above) included in a storage capacitor (e.g., the storage capacitor Cst in figures discussed above) have a single layer electrode structure (or a single metal electrode structure), and a second line (e.g., the second line SL2 in figures discussed above) has a single layer line structure (or a single metal line structure). Further, discussions are also provided based on examples where a buffer layer (e.g., the buffer layer BUF in figures discussed above) has a single layer structure.

Referring to FIGS. 10 to 20, a substrate (e.g., the substrate SUB in figures discussed above) can include a transistor area 810, a capacitor area 820, a line area 830, and the like.

Referring to FIG. 10, the light shield LS can be patterned on the substrate SUB before the buffer layer deposition process S1000 is performed.

Referring to FIG. 10, the light shield LS can be patterned in each of the transistor area 810, the capacitor area 820, and the line area 830.

For example, a light shield LS patterned in the transistor area 810 can be a pattern disposed under an active layer (e.g., the active layer ACT in figures discussed above) of a driving transistor (e.g., the driving transistor DRT in figures discussed above) and electrically connected to a source node of the driving transistor DRT.

For example, a light shield LS patterned in the capacitor area 820 can be a third capacitor electrode (e.g., the third capacitor electrode PLT3 in figures discussed above) of the storage capacitor Cst.

For example, a light shield LS patterned in the line area 830 can be the second line SL2, which is a line formed under the buffer layer BUF.

Referring to FIG. 10, in the step of the buffer layer deposition process S1000, the buffer layer BUF can be formed on the entire surface of the substrate SUB. The buffer layer BUF can include, for example, at least one of various insulating materials such as silicon nitride (SiNx), silicon dioxide (SiO2), and/or the like.

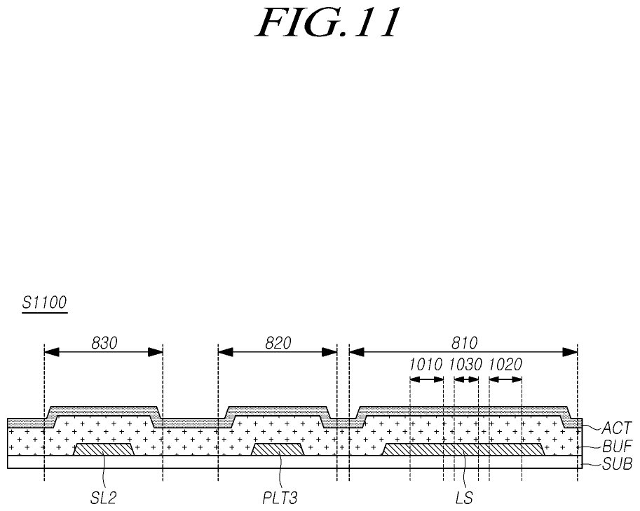

Referring to FIG. 11, in the step of the active layer deposition process S1100, the active layer ACT, for example, including an oxide semiconductor material, can be formed on the entire upper surface of the buffer layer BUF. The oxide semiconductor material can include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like.

The active layer ACT can be formed in a single layer or a multilayer. In an example where the active layer ACT is formed in a multilayer, the active layer ACT can include a multilayer formed with a same semiconductor material or a multilayer formed with two or more different semiconductor materials.

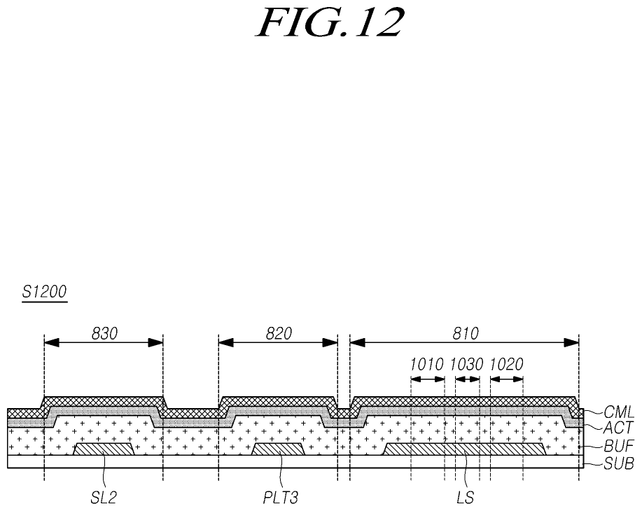

Referring to FIG. 12, in the step of the conductive material layer deposition process S1200, a conductive material CIVIL can be formed on the entire upper surface of the active layer ACT. The conductive material layer CML can include a first metal. For example, the first metal can include molybdenum (Mo), titanium (Ti), molybdenum-titanium (MoTi), or the like.

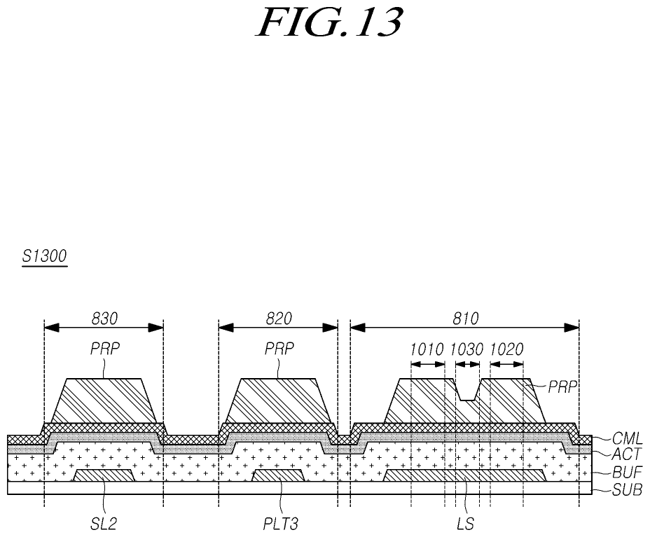

Referring to FIG. 13, in the step of the photoresist pattern forming process S1300, a photoresist pattern PRP can be formed on the conductive material layer CIVIL.

For example, a photoresist pattern PRP can be formed in the transistor area 810. The transistor area 810 can include a channel forming region 1030, a first electrode forming region 1010, and a second electrode forming region 1020.

For example, one or more photoresist patterns PRP can be further formed in one or more of the capacitor area 820 and the line area 830.

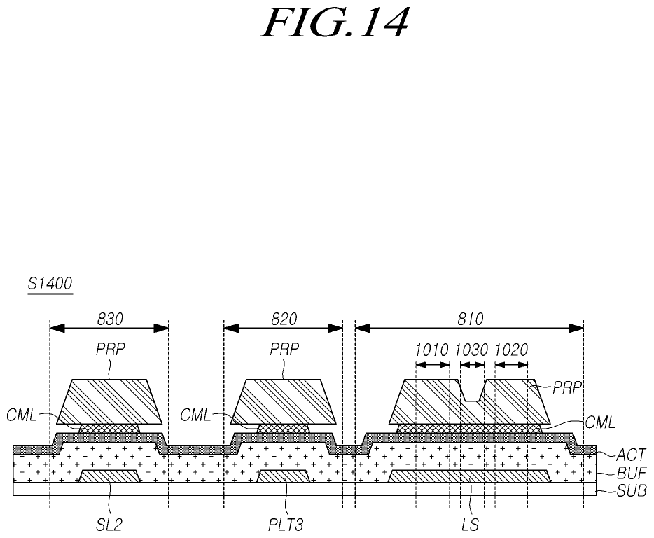

Referring to FIG. 14, in the step of the first conductive material layer etching process S1400, one or more portions of the conductive material layer CIVIL can be removed. More specifically, in the step of the first conductive material layer etching process S1400, portions of the conductive material layer CIVIL not overlapping the photoresist patterns PRP can be removed.

Referring to FIG. 14, the step of the first conductive material layer etching process S1400 can be performed by a wet etching process.

Referring to FIG. 14, after the first conductive material layer etching process S1400 is performed and before the ashing process S1500 is performed, the photoresist pattern PRP can be in a situation where a portion of the photoresist pattern PRP located in the channel forming region 1030 is thinner than a portion of the photoresist pattern PRP located in the first electrode forming region 1010 and a portion of the photoresist pattern PRP located in the second electrode forming region 1020.

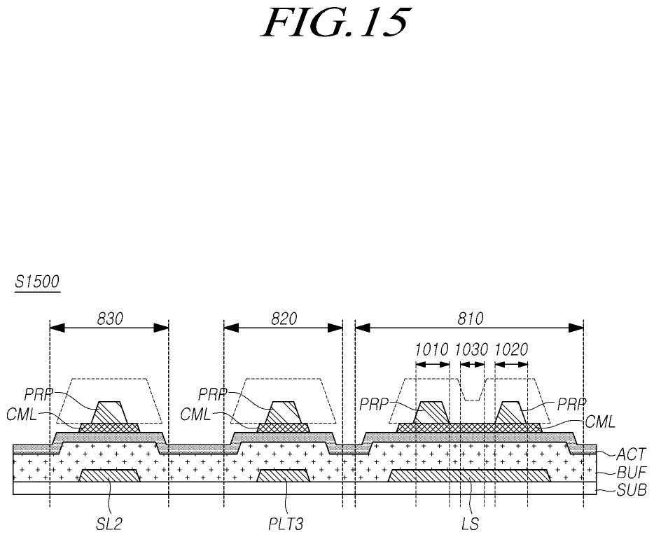

Referring to FIG. 15, in the step of the ashing process S1500, respective one or more portions of the photoresist patterns PRP can be removed. More specifically, in the ashing process S1500, a portion of the photoresist pattern PRP located in the channel forming region 1030 of the transistor area 810 can be removed.

Referring to FIG. 15, the ashing process S1500 for removing respective one or more portions of the photoresist patterns PRP can be performed in a situation where the active layer ACT is formed on the entire upper surface of the buffer layer BUF.

Referring to FIG. 15, the ashing process S1500 can be performed by a plasma ashing process using a halftone mask. Electric charges can be generated in the active layer ACT by the plasma ashing process performed in the ashing process S1500.

Referring to FIG. 15, in the ashing process S1500, as the plasma ashing process proceeds in the situation where the active layer ACT is formed on the entire upper surface of the buffer layer BUF, electric charges generated in the active layer ACT by the plasma ashing process can be discharged to the outside along the active layer ACT disposed on the entire upper surface of the buffer layer BUF. For example, while the plasma ashing process is in progress, the active layer ACT can serve as an electric charge discharging path.

Therefore, in the ashing process S1500, as the plasma ashing process proceeds in a situation where the active layer ACT is formed on the entire upper surface of the buffer layer BUF, a phenomenon in which electric charges remain at a specific location of the active layer ACT (i.e., a static electricity phenomenon) can be prevented. For example, in the ashing process S1500, as the plasma ashing process proceeds in the situation where the active layer ACT is formed on the entire upper surface of the buffer layer BUF, the static electricity phenomenon and the reduction of image quality thereby can be prevented.

If the manufacturing method according to the above embodiments of the present disclosure is not applied, the plasma ashing process can proceed in a situation where the active layer ACT is patterned into several pieces of active layer patterns. As a result, since the plurality of active layer patterns are separated, electric charges generated in at least one of the plurality of active layer patterns by the plasma ashing process can remain without being discharged. For example, if the manufacturing method according to the embodiments of the present disclosure is not applied, the static electricity phenomenon can occur in at least one of the plurality of active layer patterns. In this case, images can be different in each location depending on the presence or absence of static electricity in each of the plurality of active layer patterns, and in turn, this can be seen as stains (image stains). Locations of image stains caused by static electricity can correspond to locations of lower electrodes of plasma processing equipment.

In contrast, as described above, when the manufacturing method according to the embodiments of the present disclosure is applied, since the plasma ashing process proceeds in the situation where the active layer ACT is formed on the entire upper surface of the buffer layer BUF, electric charges generated by the plasma ashing process can be discharged along the active layer ACT formed on the entire upper surface of the buffer layer BUF. As a result, the static electricity phenomenon and the image staining phenomenon thereby can be prevented.

Referring to FIG. 15, in the ashing process S1500, since the plasma ashing process proceeds in the situation where the active layer ACT is formed on the entire upper surface of the buffer layer BUF, the entire upper surface of the buffer layer BUF under the active layer ACT cannot be damaged by the plasma ashing process.

Accordingly, surface roughness of the entire upper surface of the buffer layer BUF can become uniform. As a result, electrical characteristics of circuit elements (transistors, capacitors, and the like) formed over the buffer layer BUF can become uniform. In addition, electrical characteristics (e.g., resistance, capacitance, and the like) of lines formed over the buffer layer BUF can become uniform.

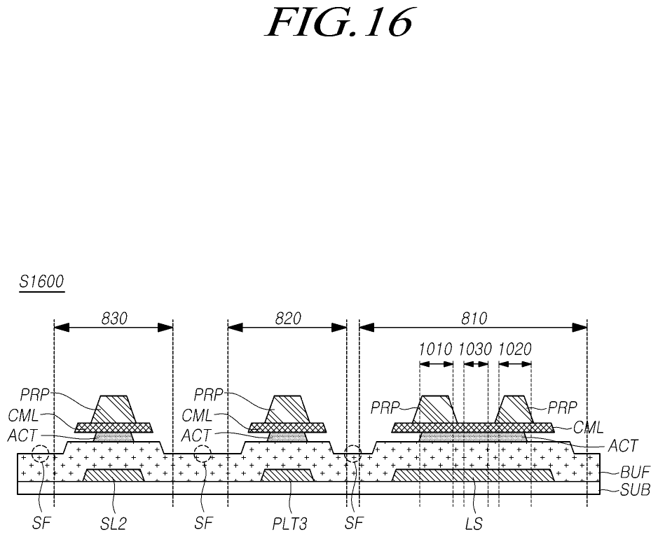

Referring to FIG. 16, the active layer etching process S1600 can proceed after the ashing process S1500 of removing respective one or more portions of the photoresist patterns PRP is performed.

Referring to FIG. 16, in the step of the active layer etching process S1600, one or more portions of the active layer ACT can be removed. More specifically, in the active layer etching process S1600, one or more portions of the active layer ACT not overlapping the conductive material layer CML can be removed. For example, the active layer etching process S1600 can be performed by the wet etching process.

Referring to FIG. 16, after the active layer etching process S1600 is performed, in a situation where one or more portions of the active layer ACT are removed, the active layer ACT may not be present in one or more portions of the upper surface of the buffer layer BUF, and can be present in one or more other portions of the upper surface of the buffer layer BUF.

As described above, since the ashing process S1500 according to the manufacturing method according to the embodiments described above is performed, after one or more portions of the active layer ACT are etched, a portion (a first portion) of the upper surface of the buffer layer BUF overlapping the active layer ACT and a portion (a second portion SF) of the upper surface of the buffer layer BUF not overlapping the active layer ACT can have uniform surface roughness.

The portion (the first portion) of the upper surface of the buffer layer BUF overlapping the active layer ACT can have a first surface roughness, and the portion (the second portion SF) of the upper surface of the buffer layer BUF not overlapping the active layer ACT can have a second surface roughness. For example, the first surface roughness and the second surface roughness can be the same as each other. In another example, the first surface roughness and the second surface roughness can be different in a predetermined range from each other.

If the manufacturing method according to the embodiments described above is not applied, the plasma ashing process can proceed in a situation where the active layer ACT is patterned into several pieces of active layer patterns. Accordingly, a step can be formed in a portion of the upper surface of the buffer layer BUF exposed by the etching of the active layer ACT, or the buffer layer BUF can be damaged. Therefore, as the manufacturing method according to the embodiments described above is not applied, if in the buffer layer BUF, a step is formed, or damage occurs, the reliability of elements located over the buffer layer BUF can be reduced. For example, a transistor on the buffer layer BUF can have a dual channel in a situation where an undesirable channel is formed due to such a step formation or damage of the buffer layer BUF. In this example, the desirable channel can be formed in an upper portion of the active layer ACT adjacent to the gate insulating layer GI, and the undesirable channel can be formed in the active layer ACT or at an interface between the buffer layer BUF and the active layer ACT.

In contrast, when the manufacturing method according to the embodiments described above is applied, since step formation cannot be made or the buffer layer BUF cannot be damaged, the reliability and characteristics of elements over the buffer layer BUF can be improved and uniform.

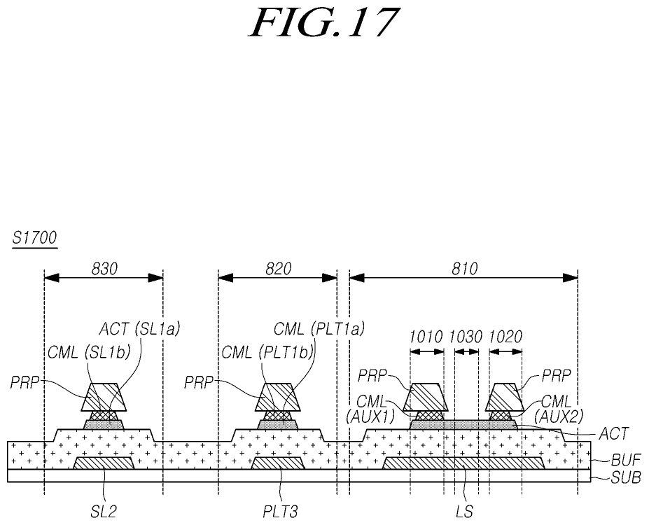

Referring to FIG. 17, the second conductive material layer etching process S1700 can proceed after the active layer etching process S1600 is performed.

Referring to FIG. 17, in the step of the second conductive material layer etching process S1700, a portion of the conductive material layer CML can be further removed. For example, in the first conductive material layer etching process S1400, one or more portions of the conductive material layer CIVIL can be removed once, and thereafter, in the second conductive material layer etching process S1700, respective one or more portions of remaining one or more portions of the conductive material layer CIVIL can be further removed. The second conductive material layer etching process S1700 can be performed by the wet etching process.

Referring to FIG. 17, in the second conductive material layer etching process S1700, a portion of the conductive material layer CML not overlapping the photoresist patterns PRP and not overlapping the channel forming region 1030 can be further removed.

Referring to FIG. 17, after the second conductive material layer etching process S1700 is performed, the conductive material layer CML can remain in the first electrode forming region 1010 and the second electrode forming region 1020, among the channel forming region 1030, the first electrode forming region 1010, and the second electrode forming region 1020, which are included in the transistor area 810.

Referring to FIG. 17, after the second conductive material layer etching process S1700 is performed, a portion of the conductive material layer CIVIL remaining in the first electrode forming region 1010 can serve as a first auxiliary electrode (e.g., the first auxiliary electrode AUX1 in figures discussed above), and a portion of the conductive material layer CML remaining in the second electrode forming region 1020 can serve as a second auxiliary electrode (e.g., the second auxiliary electrode AUX2 in figures discussed above).

Accordingly, the first auxiliary electrode AUX1 and the second auxiliary electrode AUX2 of the driving transistor DRT can be formed through the second conductive material layer etching process S1700.

Referring to FIG. 17, after the second conductive material layer etching process S1700 is performed, the conductive material layer CIVIL can remain in the capacitor area 820.

Referring to FIG. 17, after the second conductive material layer etching process S1700 is performed, a portion of the conductive material layer CML remaining in the capacitor area 820 can serve as a first upper capacitor electrode (e.g., the first upper capacitor electrode PLT1b in figures discussed above) included in a first capacitor electrode (e.g., the first capacitor electrode PLT1 in figures discussed above) of the storage capacitor Cst.

After the second conductive material layer etching process S1700 is performed, a portion of the active layer ACT located under a portion of the conductive material layer CML remaining in the capacitor area 820 can serve as a first lower capacitor electrode (e.g., the first lower capacitor electrode PLT1a in figures discussed above) included in the first capacitor electrode PLT1 of the storage capacitor Cst. The portion of the active layer ACT serving as the first lower capacitor electrode PLT1a can be formed in the active layer etching process S1600.

Accordingly, the first capacitor electrode PLT1 of the storage capacitor Cst can be formed through the second conductive material layer etching process S1700.

Referring to FIG. 17, after the second conductive material layer etching process S1700 is performed, the conductive material layer CIVIL can remain in the line area 830.

Referring to FIG. 17, after the second conductive material layer etching process S1700 is performed, a portion of the conductive material layer CML remaining in the line area 830 can serve as a first upper line (e.g., the first upper line SL1b in figures discussed above) included in a first line (e.g., the first line SL1 in figures discussed above).

After the second conductive material layer etching process S1700 is performed, a portion of the active layer ACT located under the portion of the conductive material layer CML remaining in the line area 830 can serve as a first lower line (e.g., the first lower line SL1a in figures discussed above) included in the first line SL1. The portion of the active layer ACT serving as the first lower line SL1a can be formed in the active layer etching process S1600.

Therefore, the first line SL1, which is a line located over the buffer layer BUF, can be formed through the second conductive material layer etching process S1700.

Referring to FIGS. 15 and 16, since the active layer ACT is patterned by the active layer etching process S1600 after the ashing process S1500 is performed, the active layer ACT of the driving transistor DRT can have a shorter tail. Accordingly, the aperture ratio of the display panel 110 can be increased.

Referring to FIG. 17, a tail of the active layer ACT of the driving transistor DRT is a portion beyond, among first and second ends of the first auxiliary electrode AUX1, the first end farther away from the second auxiliary electrode AUX2, and is an undesirable by-product formed during the processes. A tail of the active layer ACT of the driving transistor DRT is a portion beyond, among first and second ends of the second auxiliary electrode AUX2, the second end farther away from the first auxiliary electrode AUX1, and is an undesirable by-product formed during the processes.

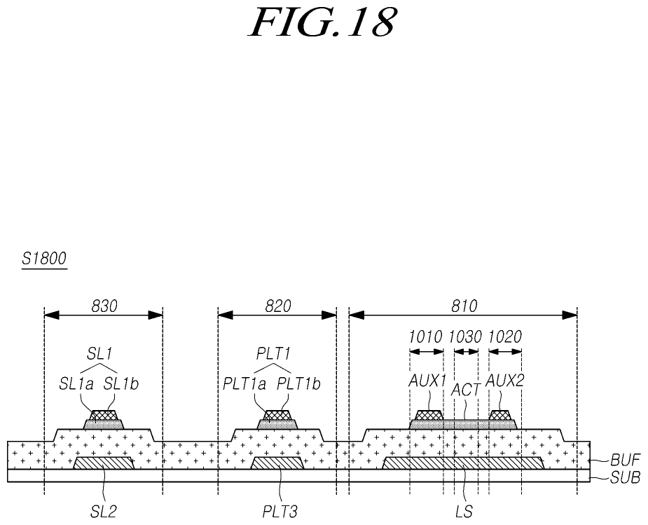

Referring to FIG. 18, after the secondary conductive material layer etching process S1700 is performed, the photoresist pattern removing process S1800 can be performed, and thereby, all of the remaining photoresist pattern PRP can be removed.

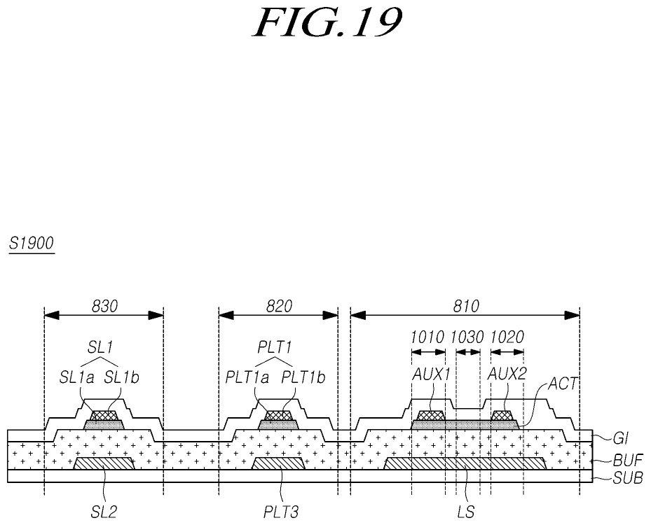

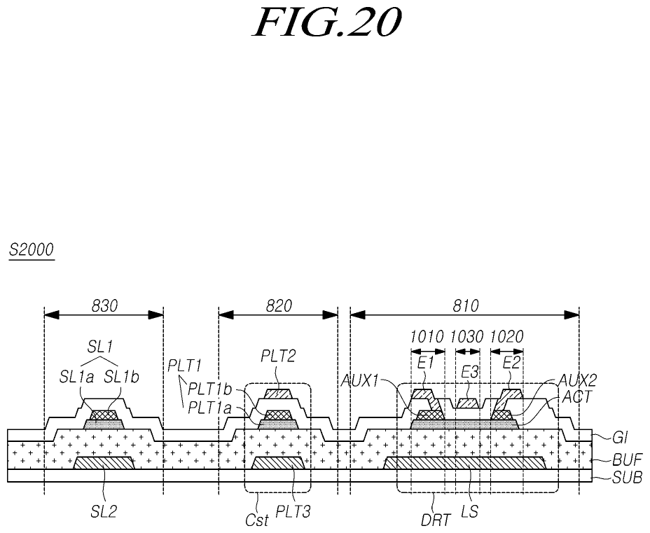

Referring to FIGS. 19 and 20, after the photoresist pattern removing process S1800 is performed, the gate insulating layer forming process S1900 and the transistor electrode forming process S2000 can be performed.

Referring to FIG. 19, in the gate insulating layer forming process S1900, a gate insulating layer (e.g., the gate insulating layer GI in figures discussed above) can be formed such that the gate insulating layer GI covers all of the first line SL1, the first capacitor electrode PLT1, the first auxiliary electrode AUX1, and the second auxiliary electrode AUX2, which are formed with respective portions of the conductive material layer CIVIL.

In the gate insulating layer forming process S1900, an etching process suitable for the gate insulating layer etch structure and the gate insulating layer etch-less structure of the display panel 110 can be further performed.

Referring to FIG. 20, the first electrode E1 electrically connected to the first auxiliary electrode AUX1, the second electrode E2 electrically connected to the second auxiliary electrode AUX2, and the third electrode E3 located on the gate insulating layer GI and located in the channel forming region 1030 can be formed in the transistor electrode forming process S2000.

Referring to FIG. 20, the first electrode E1, the second electrode E2, and the third electrode E3 can be formed on the gate insulating layer GI.

Referring to FIG. 20, the first electrode E1 can be electrically connected to the first auxiliary electrode AUX1 through a hole of the gate insulating layer GI, and the second electrode E2 can be electrically connected to the second auxiliary electrode AUX2 through another hole of the gate insulating layer GI. The third electrode E3 can be formed to overlap the channel region CHA of the active layer ACT on the gate insulating layer GI.

Referring to FIG. 20, in the transistor electrode forming process S2000, the first electrode E1, the second electrode E2, and the third electrode E3 are formed in a multilayer electrode structure (double metal structure).

For example, as shown in FIGS. 5, 6, 8, and 9, the first electrode E1 can include the first lower electrode Ela and the first upper electrode E1b electrically connected to each other, and the second electrode E2 can include the second lower electrode E2a and the second upper electrode E2b electrically connected to each other, and the third electrode E3 can include the third lower electrode E3a and the third upper electrode E3b electrically connected to each other.

The first lower electrode E1a, the second lower electrode E2a, and the third lower electrode E3a can commonly include a first metal. The first upper electrode E1b, the second upper electrode E2b, and the third upper electrode E3b can commonly include the second metal different from the first metal.

For example, a conductive material included in the first and second auxiliary electrodes AUX1 and AUX2 can include the metal included in the third electrode E3. In an example where the third electrode E3 has a multilayer electrode structure (double metal structure), the conductive material included in the first and second auxiliary electrodes AUX1 and AUX2 can include the metal included in the lower electrode E3a of the third electrode E3.

In another example, the conductive material included in the first and second auxiliary electrodes AUX1 and AUX2 can include a transparent conductive oxide.

The conductive material included in the first and second auxiliary electrodes AUX1 and AUX2 can include a conductive oxide. For example, the conductive oxide can include at least one of a transparent conductive oxide (TCO), a nitroxide, an organic material, and the like. For example, the transparent conductive oxide (TCO) can include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), fluorine-doped transparent oxide (FTO), and the like. The nitric oxide can include zinc oxynitride (ZnON), and the like.

According to the embodiments described herein, since the ashing process proceeds in a situation where the active layer ACT is formed on the entire upper surface of the buffer layer BUF, the buffer layer BUF can have uniform surface roughness. Thereby, characteristics and reliability of elements disposed on the buffer layer can be improved.

According to the embodiments described herein, since the ashing process proceeds in a situation where the active layer ACT is formed on the entire upper surface of the buffer layer BUF, electric charges can be discharged along the active layer formed on the entire surface of the buffer layer, and thereby static electricity can be prevented.

According to the embodiments described herein, since the ashing process proceeds in a situation where the active layer ACT is formed on the entire upper surface of the buffer layer BUF, while the ashing process is performed, the active layer ACT can be uniformity affected across the entire area thereof (e.g., for a damage to the active layer ACT by ashing, a change in temperature caused by a lower electrode of plasma equipment, and/or the like). Accordingly, display artifacts such as the image stain phenomenon that can be caused by a non-uniform characteristic change of the active layer ACT through the ashing process can be prevented or minimized.

According to the embodiments described herein, since the active layer ACT is patterned through the active layer etching process after the ashing process is performed, the active layer ACT of the transistor can have a short tail. Accordingly, the aperture ratio of the display panel can be increased to provide an improved display device.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention. Thus, the scope of the present invention is not limited to the embodiments shown, but is to be accorded the widest scope consistent with the claims. The scope of protection of the present invention should be construed based on the following claims, and all technical ideas within the scope of equivalents thereof should be construed as being included within the scope of the present invention.

What is claimed is:

1. A display device comprising:
a buffer layer located on a substrate;
an active layer located located on the buffer layer, and including a channel region, a first region located on a first side of the channel region, and a second region located on a second side of the channel region;
a first conductor located on the first region of the active layer; and
a second conductor located on the second region of the active layer,
wherein in the buffer layer,
a portion of an upper surface overlapping the active layer has a first surface roughness, and
a portion of the upper surface not overlapping the active layer has a second surface roughness, and
wherein the first surface roughness and the second surface roughness are same, or are different in a predetermined range from each other.

2. The display device of claim 1, further comprising:
a gate insulating layer located on the channel region;
a first electrode electrically connected to the first conductor;
a second electrode electrically connected to the second conductor; and
a third electrode located on the gate insulating layer and overlapping the channel region,
wherein the first conductor is a first auxiliary electrode for an electrical connection between the first region and the first electrode, and the second conductor is a second auxiliary electrode for an electrical connection between the second region and the second electrode.

3. The display device of claim 2, wherein a conductive material included in the first conductor and the second conductor comprises either a metal included in the third electrode or a transparent conductive oxide.

4. The display device of claim 2, wherein the gate insulating layer comprises:
a first gate insulating layer part disposed so that the first gate insulating layer part covers, among first and second ends of the first conductor, the first end farther away from the channel region;
a second gate insulating layer part disposed so that the second gate insulating layer part covers, among first and second ends of the second conductor, the second end farther away from the channel region; and
a third gate insulating layer part located on the channel region,
wherein the first electrode is located on one or more upper surfaces and one or more side surfaces of the first gate insulating layer part, and contacts a portion of an upper surface of the first conductor while being located on a side surface of the first gate insulating layer part,
wherein the second electrode is located on one or more upper surfaces and one or more side surfaces of the second gate insulating layer part, and contacts a portion of an upper surface of the second conductor while being located on a side surface of the second gate insulating layer part, and
wherein the third electrode is located on an upper surface of the third gate insulating layer part.

5. The display device of claim 2, wherein the first electrode comprises a first lower electrode and a first upper electrode electrically connected to each other,
wherein the second electrode comprises a second lower electrode and a second upper electrode electrically connected to each other,
wherein the third electrode comprises a third lower electrode and a third upper electrode electrically connected to each other, and
wherein the first lower electrode, the second lower electrode, and the third lower electrode commonly comprise a first metal, and the first upper electrode, the second upper electrode, and the third upper electrode commonly comprise a second metal different from the first metal.

6. The display device of claim 5, further comprising a light shield located between the substrate and the buffer layer and overlapping the channel region,
wherein the light shield comprises a lower light shield and an upper light shield located on the lower light shield,
wherein the lower light shield comprises the first metal included in the first lower electrode, the second lower electrode, and the third lower electrode, and
wherein the upper light shield comprises the second metal included in the first upper electrode, the second upper electrode, and the third upper electrode.

7. The display device of claim 6, wherein the first lower electrode or the second lower electrode is connected to the upper light shield through through-holes of the buffer layer and the gate insulating layer.

8. The display device of claim 2, further comprising:
a transistor disposed in a display area or a non-display area, and comprising the active layer, the first conductor, the second conductor, the first electrode, the second electrode, and the third electrode;
a line for delivering a signal; and
a light shield located between the substrate and the buffer layer and overlapping the channel region,
wherein the line comprises a lower line and an upper line electrically connected to each other,
wherein the lower line comprises an oxide semiconductor included in the active layer, and the upper line comprises a conductive material included in the first conductor and the second conductor,
wherein a portion of an upper surface of the buffer layer contacting the lower line has a third surface roughness, and a portion of the upper surface of the buffer layer not overlapping the lower line and not overlapping a semiconductor material included in the active layer has a fourth surface roughness, and
wherein the third surface roughness and the fourth surface roughness are same or are different in a predetermined range from each other.

9. The display device of claim 2, further comprising:
a driving transistor disposed in a display area and comprising the active layer, the first conductor, the second conductor, the first electrode, the second electrode, and the third electrode;
a storage capacitor connected between the first electrode and the third electrode of the driving transistor; and
a light shield located between the substrate and the buffer layer and overlapping the channel region,
wherein the storage capacitor comprises a first capacitor electrode, a second capacitor electrode located over the first capacitor electrode, and a third capacitor electrode located under the first capacitor electrode,
wherein the gate insulating layer is located between the first capacitor electrode and the second capacitor electrode, and the buffer layer is located between the first capacitor electrode and the third capacitor electrode,
wherein a portion of an upper surface of the buffer layer contacting the first capacitor electrode has a fifth surface roughness, and a portion of the upper surface of the buffer layer not overlapping the first capacitor electrode and not overlapping a semiconductor material included in the active layer has a sixth surface roughness, and
wherein the fifth surface roughness and the sixth surface roughness are same or are different in a predetermined range from each other.

10. The display device of claim 9, wherein the first capacitor electrode comprises an oxide layer and a metal layer located on the oxide layer,
wherein the oxide layer comprises an oxide semiconductor included in the active layer, and the metal layer comprises a conductive material included in the first conductor and the second conductor, and
wherein the third capacitor electrode comprises a metal included in the light shield, and the second capacitor electrode comprises a metal included in the third electrode.

11. The display device of claim 1, wherein at a boundary with an edge of the active layer, the first surface roughness has a difference in a range of about 10% from the second surface roughness.

12. The display device of claim 1, wherein at a boundary with an edge of the active layer, a difference in height between a portion of an upper surface of the buffer layer overlapping the active layer and a portion of the upper surface of the buffer layer not overlapping the active layer is present.

13. A method of manufacturing a display device, the method comprising:
forming a buffer layer on an entire surface of a substrate;
forming an active layer on an entire upper surface of the buffer layer;
forming a conductive material layer on an entire upper surface of the active layer;
whiling forming one or more photoresist patterns on the conductive material layer, forming a photoresist pattern in a transistor area comprising a channel forming region, a first electrode forming region, and a second electrode forming region;
while removing one or more portions of the conductive material layer, removing a portion of the conductive material layer not overlapping the one or more photoresist patterns; and
while removing respective one or more portions of the one or more photoresist patterns, removing a portion of the photoresist pattern located in the channel forming region of the transistor area,
wherein the removing of the respective one or more portions of the one or more photoresist patterns is performed in a situation where the active layer is formed on the entire upper surface of the buffer layer.

14. The method of claim 13, wherein the removing of the respective one or more portions of the one or more photoresist patterns is performed by using a plasma ashing process, and electric charges generated in the active layer by the plasma ashing process are thereby discharged along the active layer formed on the entire upper surface of the buffer layer.

15. The method of claim 13, wherein the removing of the one or more portions of the conductive material layer is performed by using a wet etching process.

16. The method of claim 13, further comprising:
after the removing of the respective one or more portions of the one or more photoresist patterns is performed, while removing one or more portions of the active layer, removing a portion of the active layer not overlapping the conductive material layer; and
while further removing respective one or more portions of remaining one or more portions of the conductive material layer, removing a portion of the conductive material layer not overlapping the one or more photoresist patterns and not overlapping the channel forming region.

17. The method of claim 16, wherein after the removing of the one or more portions of the active layer is performed, a portion of the upper surface of the buffer layer overlapping the active layer has a first surface roughness, and a portion of the upper surface of the buffer layer not overlapping the active layer has a second surface roughness, and
wherein the first surface roughness and the second surface roughness are same or are different in a predetermined range from each other.

18. The method of claim 17, wherein at a boundary with an edge of the active layer, the first surface roughness has a difference in a range of about 10% from the second surface roughness.

19. The method of claim 17, wherein at a boundary with an edge of the active layer, a difference in height between a portion of the upper surface of the buffer layer overlapping the active layer and a portion of the upper surface of the buffer layer not overlapping the active layer is present.

20. The method of claim 16, wherein after the further removing of the respective one or more portions of remaining one or more portions of the conductive material layer is performed, the conductive material layer remains in the first electrode forming region and the second electrode forming region,
wherein a portion of the conductive material layer remaining in the first electrode forming region serves as a first auxiliary electrode, and a portion of the conductive material layer remaining in the second electrode forming region serves as a second auxiliary electrode, and
wherein the method further comprises:
after the further removing of the respective one or more portions of remaining one or more portions of the conductive material layer is performed, forming a gate insulating layer; and
forming a first electrode electrically connected to the first auxiliary electrode, a second electrode electrically connected to the second auxiliary electrode, and a third electrode located on the gate insulating layer and disposed in the channel forming region.

21. The method of claim 20, wherein the first electrode comprises a first lower electrode and a first upper electrode electrically connected to each other,
wherein the second electrode comprises a second lower electrode and a second upper electrode electrically connected to each other,
wherein the third electrode comprises a third lower electrode and a third upper electrode electrically connected to each other, and
wherein the first lower electrode, the second lower electrode, and the third lower electrode commonly comprise a first metal, and the first upper electrode, the second upper electrode, and the third upper electrode commonly comprise a second metal different from the first metal.

22. The method of claim 20, wherein a conductive material included in the first conductor and the second conductor comprises either a metal included in the third electrode or a transparent conductive oxide.
